(19) United States
(12) Patent Application Publication
(10) Pub. No.: US 2025/0081461 A1
(43) Pub. Date: Mar. 6, 2025

(54) SEMICONDUCTOR DEVICE INCLUDING STACKED DATA LINES

(71) Applicant: Micron Technology, Inc., Boise, ID (US)

(72) Inventor: Darwin A. Clampitt, Wilder, ID (US)

(21) Appl. No.: 18/775,247

(22) Filed: Jul. 17, 2024

Related U.S. Application Data
(60) Provisional application No. 63/535,936, filed on Aug. 31, 2023.

(51) Int. Cl. H10B 43/27; H10B 41/27

(52) U.S. Cl. CPC H10B 43/27; H10B 41/27

(57) ABSTRACT

Some embodiments include apparatuses and methods of forming the apparatuses. One of the apparatuses includes a conductive contact, a conductive portion formed over the conductive contact, and data lines located over the first conductive portion and separated from the first conductive portion by a dielectric material, the data lines formed from respective levels of conductive materials, and a conductive structure located on a side of the levels of conductive materials. The levels of conductive materials are stacked one over another in a first direction in different levels of the apparatus. The conductive structure includes a first portion and a second portion. The first portion extends in the first direction and coupled to a level of conductive material among the levels of conductive materials. The second portion extends in a second direction and coupled to the conductive portion.

### PRIORITY APPLICATION

This application claims the benefit of priority to U.S. Provisional Application Ser. No. 63/535,936, filed Aug. 31, 2023, which is incorporated herein by reference in its entirety.

### BACKGROUND

Semiconductor devices such as memory devices are widely used in computers and many other electronic items to store information. A memory device often includes memory cells and data lines to carry information (in the form of signals) to and from the memory cells. As demand for memory cell density for a given device area increases, the number of data lines may also increase to keep pace with the increased memory cell density. However, because of area limitation in some conventional memory devices, increasing the number of data lines in such conventional memory devices may pose a challenge.

### BRIEF DESCRIPTION OF THE DRAWINGS

FIG. 1 shows a portion of a schematic diagram of an apparatus in the form of a memory device having sets of data lines, according to an embodiment of the invention.

FIG. 2 shows a schematic diagram of a portion of the memory device of FIG. 1 including an example where the memory device includes eight data lines in each set of data lines, according to an embodiment of the invention.

FIG. 3A shows a side view (e.g., a cross section with respect to the Z-Y directions) of a structure of a portion of the memory device of FIG. 2 including the structure of a set of data lines and a structure of a memory cell string of the memory device of FIG. 2, according to some embodiments described herein.

FIG. 3B shows a top view (e.g., a cross section with respect to the X-Y plane) of a portion of a pillar of a memory cell string of FIG. 3A, according to some embodiments described herein.

FIG. 3C shows a top view (e.g., a cross section with respect to the X-Y plane) of a conductive contact of a pillar of a memory cell string of FIG. 3A, according to some embodiments described herein.

FIG. 4 shows a top view of a structure of the memory device including data lines and conductive contacts (e.g., drain contacts) of respective memory cell strings of the memory device of FIG. 2, according to some embodiments described herein.

FIG. 5 shows an isometric view of portion of a structure of the memory device of FIG. 4 including a memory cell area and the stacks of data lines of the memory device, according to some embodiments described herein.

FIG. 6 shows a top view of a structure of the memory device of FIG. 1 and FIG. 2 including blocks of memory cells and the stacks of data lines of the memory device, according to some embodiments described herein.

FIG. 7 through FIG. 52C show different views of elements during processes of forming a memory device including forming stacks of data lines of the memory device, according to some embodiments described herein.

### DETAILED DESCRIPTION

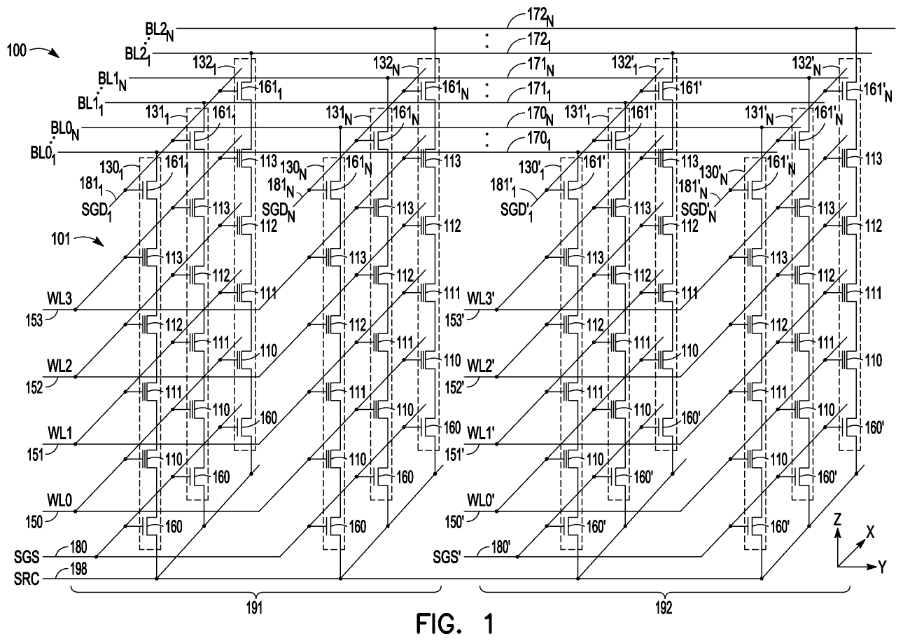

The techniques described herein include a memory device having stacked data lines where the data lines are stacked over one another in different levels (vertical levels) of the memory device. The stacked structure of the data lines described herein can increase the density of the data lines for a given area. This can allow more memory cells to be coupled to the data lines. This can increase memory cell density for a given area of the described memory device. Other improvements and benefits of the described techniques are discussed below with reference to FIG. 1 through FIG. 52C.

FIG. 1 shows a portion of a schematic diagram of an apparatus in the form of a memory device 100 having sets of data lines, according to an embodiment of the invention. Memory device 100 can include a non-volatile (e.g., NAND flash memory device) or other types of memory devices. As shown in FIG. 1, memory device 100 can include a memory cell area (e.g., memory array area) 101 (which has memory cells 110, 111, 112, and 113) and data lines (a set of data lines) 170₁ through 170_{N}, data lines (a set of data lines) 171₁ through 171_{N}, and data lines (a set of data lines) 172₁ through 172_{N}. Data lines 170₁ through 170_{N}, 171₁ through 171_{N}, and 172₁ through 172_{N} can include (or can be part of) bit lines (e.g., local bit lines) of memory device 100.

Memory device 100 can include an equal number of data lines among the sets (e.g., the stacks) of the data lines. In FIG. 1, label “N” (the number of data lines in each set of data lines) can be any integer at least equal to two (N can be equal to two (N=2) or N can be greater than two (N>2)).

As shown in FIG. 1, data lines 170₁ through 170_{N} can carry signals (e.g., bit line signals) BL0₁ through BL0_{N}, respectively. Data lines 171₁ through 171_{N} can carry signals (e.g., bit line signals) BL1₁ through BL1_{N}, respectively. Data lines 172₁ through 172_{N} can carry signals (e.g., bit line signals) BL2₁ through BL2_{N}, respectively.

FIG. 1 shows directions X, Y, and Z that can be relative to the physical directions (e.g., dimensions) of the structure of memory device 100. For example, the Z-direction can be a direction perpendicular to (e.g., vertical direction relative to) a substrate (e.g., a semiconductor substrate) of memory device 100. The Z-direction is perpendicular to the X-direction and Y-direction (e.g., the Z-direction is perpendicular to an X-Y plane of memory device 100).

In the physical structure of memory device 100, data lines 170₁ through 170_{N}, data lines 171₁ through 171_{N}, and data lines 172₁ through 172_{N} can be structured as conductive lines and have respective lengths extending in the Y-direction. As described in more detail below, the data lines (e.g., data lines 170₁ through 170_{N}) within the same set of data lines (e.g., data lines 170₁ through 170_{N}) can be formed in a stack structure. In the stack structure, the data lines within the same set can be located (e.g., stacked) one over another in different levels (e.g., layers) in the Z-direction over memory cell area 101 of memory device 100. For example, in a physical structure of memory device 100, data lines 170₁ through 170_{N}, data lines 171₁ through 171_{N}, and data lines 172₁ through 172_{N} can be formed in respective stacks (e.g., side-by-side stacks in the X-direction) over memory cell area 101. For example, data lines 170₁ through 170_{N} can be formed in a stack (e.g., first stack of data lines), data lines 171₁ through 171_{N} can be formed in another stack (e.g., a second stack of data lines next to the first stack), and data lines 172₁ through 172_{N} can be formed in a stack (e.g., a third stack of data lines next to the second stack).

FIG. 1 shows memory device 100 including an example of three sets of data lines (e.g., the set of data lines 170₁ through 170_{N}, the set of data lines 171₁ through 171_{N}, and the set of data lines 172₁ through 172_{N}). However, memory device 100 can include numerous sets of data lines.

As shown in FIG. 1, memory cells 110, 111, 112, and 113 can be organized into blocks (blocks of memory cells). FIG. 1 shows memory device 100 including two blocks 191 and 192 as an example. However, memory device 100 can include numerous blocks. The blocks (e.g., blocks 191 and 192) of memory device 100 can share data lines (e.g., data lines 170₁ through 170_{N}, 171₁ through 171_{N}, and 172₁ through 172_{N}) to carry information (in the form of signals) read from or to be stored in memory cells of selected memory cells (e.g., selected memory cells in block 191 or 192) of memory device 100.

As shown in FIG. 1, memory cells 110, 111, 112, and 113 can be included in (e.g., can be formed as) respective memory cell strings in each of the blocks (e.g., blocks 191 and 192) of memory device 100. For example, in block 191, memory device 100 can include memory cell strings 1301 through 130_{N}, memory cell strings 131₁ through 131_{N}, and memory cell strings 1321 through 132N. In another example, in block 192, memory device 100 can include memory cell strings 130′₁ through 130′_{N}, memory cell strings 131′₁ through 131′_{N}, and memory cell strings 132′1 through 132′_{N}.

In each block (e.g., block 191 or 192) of memory device 100, the number of memory strings in the X-direction that are coupled to a set of data lines can be equal to the number (e.g., N) of data lines of the set of data lines.

As shown in FIG. 1, each memory cell string (e.g., memory cell string 1301) of memory device 100 can have series-connected memory cells (e.g., four series-connected memory cells) where series-connected memory cells can include one of memory cells 110, one of memory cells 111, one of memory cells 112, and one of memory cells 113. In a physical structure of memory device 100, memory cells 110, 111, 112, and 113 can be formed (e.g., formed vertically) in different levels (e.g., four different layers) in the Z-direction of memory device 100 and under the stack structures of data lines 170₁ through 170_{N}, 171₁ through 171_{N}, and 172₁ through 172_{N}). FIG. 1 shows an example of four memory cells in each memory cell strings (e.g., memory cells 110, 111, 112 and 113 in memory cell string 1301). However, the number of memory cells in each memory cell string of memory device 100 can vary.

As shown in FIG. 1, memory device 100 can include control gates 150, 151, 152, and 153 that can carry corresponding signals WL0, WL1, WL2, and WL3. Control gates 150, 151, 152, and 153 can include (or can be parts of) access lines (e.g., word lines) of memory device 100. Each of control gates 150, 151, 152, and 153 can be part of a structure (e.g., a level) of a conductive material (e.g., a layer of conductive material) located in a single level of memory device 100. Memory device 100 can use signals WL0, WL1, WL2, and WL3 to control access to memory cells 110, 111, 112, and 113, respectively, of block 191 during an operation (e.g., read, write, or erase operation). For example, during a read operation, memory device 100 can use signals WL0, WL1, WL2, and WL3 to control access to memory cells 110, 111, 112, and 113 of block 191 to read (e.g., sense) information (e.g., previously stored information) from memory cells 110, 111, 112, and 113 of block 191. In another example, during a write operation, memory device 100 can use signals WL0, WL1, WL2, and WL3 to control access to memory cells 110, 111, 112, and 113 of block 191 to store information in memory cells 110, 111, 112, and 113 to block 191.

Memory device 100 can include similar control gates in block 192. For example, memory device can include control gates 150′, 151′, 152′, and 153′ that can carry corresponding signals WL0′, WL1′, WL2′, and WL3′. Each of control gates 150′, 151′, 152′, and 153′ can be part of a structure (e.g., a level) of a conductive material (e.g., a layer of conductive material) located in a single level of memory device 100. Control gates 150′, 151′, 152′, and 153′ can be located in the same level as control gates 150, 151, 152, and 153, respectively. As shown in FIG. 1, control gates 150′, 151′, 152′, and 153′ can be electrically separated from control gates 150, 151, 152, and 153. Thus, the access lines that include control gates 150, 151, 152, and 153 can be electrically separated from the access lines that include control gates control gates 150′, 151′, 152′, and 153′.

Memory device 100 can use signals WL0′, WL1′, WL2′, and WL3′ to control access to memory cells 110, 111, 112, and 113, respectively, of block 192 during an operation (e.g., read, write, or erase operation). For example, during a read operation, memory device 100 can use signals WL0′, WL1′, WL2′, and WL3′ to control access to memory cells 110, 111, 112, and 113 of block 192 to read (e.g., sense) information (e.g., previously stored information) from memory cells 110, 111, 112, and 113 of block 192. In another example, during a write operation, memory device 100 can use signals WL0′, WL1′, WL2′, and WL3′ to control access to memory cells 110, 111, 112, and 113 of block 192 to store information in memory cells 110, 111, 112, and 113 to block 192.

As shown in FIG. 1, memory cells in different memory cell strings in the same block can share the same control gate (e.g., share the same physical control gate) in that block. For example, in block 191, memory cells 110 can share control gate 150, memory cells 111 can share control gate 151, memory cells 112 can share control gate 152, and memory cells 113 can share control gate 153. In block 192, memory cells 110 can share control gate 150′, memory cells 111 can share control gate 151′, memory cells 112 can share control gate 152′, and memory cells 113 can share control gate 153′.

FIG. 1 shows four control gates in each block (e.g., control gates 150, 151, 152, and 153 in block 191) of memory device 100 as an example. The number of control gates in each block of memory device 100 can vary (e.g., can be more than four).

As shown in FIG. 1, memory device 100 can include a line (e.g., a source line or a source plate) 198 that can carry a signal (e.g., a source line signal) SRC. Line 198 can be structured as a conductive line or a conductive plate of memory device 100. Line 198 can be common conductive line (e.g., a common source line or a common source plate) of blocks 191 and 192. Line 198 can be coupled to a ground connection of memory device 100.

Memory device 100 can include select gates (e.g., drain select gates) 181₁ through 181_{N}, and transistors (e.g., drain select transistors) 161₁ through 161_{N}. Transistors 161₁ can share the same select gate 181₁. Transistors 161_{N} can share the same select gate 181_{N}. Select gates 181₁ through 181_{N} can carry signals SGD₁ through SGD_{N}, respectively.

Transistors 161₁ through 161_{N} can be controlled (e.g., turned on or turned off) by signals SGD₁ through SGD_{N}, respectively. During a memory operation (e.g., a read or write operation) of memory device 100, transistors 161₁ through 161_{N} can be turned on (e.g., by activating respective signals SGD₁ through SGD_{N}) to couple the memory cell strings of block 191 to respective sets of data lines 170₁ through 170_{N}, 171₁ through 171_{N}, and 172₁ through 172_{N}. Transistors 161₁ through 161_{N} can be turned off (e.g., by deactivating respective signals SGD₁ through SGD_{N}) to decouple the memory cell strings of block 191 from respective sets of data lines 170₁ through 170_{N}, 171₁ through 171_{N}, and 172₁ through 172_{N}.

Memory device 100 can include transistors (e.g., source select transistors) 160, each of which can be coupled between line 198 and the memory cells in a respective memory cell string of block 191. Transistors 160 can share the same select gate (e.g., source select gate) 180 of memory device 100. Transistors 160 can be controlled (e.g., turned on or turned off) by the same signal, such as SGS signal (e.g., source select gate signal) provided on select gate 180. During a memory operation (e.g., a read or write operation) of memory device 100, transistors 160 can be turned on (e.g., by activating an SGS signal) to couple the memory cell strings of block 191 to line 198. Transistors 160 can be turned off (e.g., by deactivating the SGS signal) to decouple the memory cell strings of block 191 from line 198.

Memory device 100 can include similar select gates and transistors in block 192. For example, memory device 100 can include select gates (e.g., drain select gates) 181′₁ through 181′_{N}, and transistors (e.g., drain select transistors) 161′₁ through 161′_{N}. Transistors 161′₁ can share the same select gate 181′₁. Transistors 161′_{N} can share the same select gate 181′_{N}. Select gates 181′₁ through 181′_{N} can carry signals SGD′₁ through SGD′_{N}, respectively.

Transistors 161′₁ through 161′_{N} can be controlled (e.g., turned on or turned off) by signals SGD′₁ through SGD′_{N}, respectively. During a memory operation (e.g., a read or write operation) of memory device 100, transistors 161′₁ through 161′_{N} can be turned on (e.g., by activating respective signals SGD′₁ through SGD′_{N}) to couple the memory cell strings of block 192 to respective sets of data lines 170₁ through 170_{N}, 171₁ through 171_{N}, and 172₁ through 172_{N}. Transistors 161′1 through 161′_{N} can be turned off (e.g., by deactivating respective signals SGD′₁ through SGD′_{N}) to decouple the memory cell strings of block 192 from respective sets of data lines 170₁ through 170_{N}, 171₁ through 171_{N}, and 172₁ through 172_{N}.

Memory device 100 can include transistors (e.g., source select transistors) 160′, each of which can be coupled between line 198 and the memory cells in a respective memory cell string of block 192. Transistors 160′ can share the same select gate (e.g., source select gate) 180′ of memory device 100. Transistors 160′ can be controlled (e.g., turned on or turned off) by the same signal, such as SGS' signal (e.g., source select gate signal) provided on select gate 180′. During a memory operation (e.g., a read or write operation) of memory device 100, transistors 160′ can be turned on (e.g., by activating an SGS' signal) to couple the memory cell strings of block 192 to line 198. Transistors 160′ can be turned off (e.g., by deactivating the SGS' signal) to decouple the memory cell strings of block 192 from line 198.

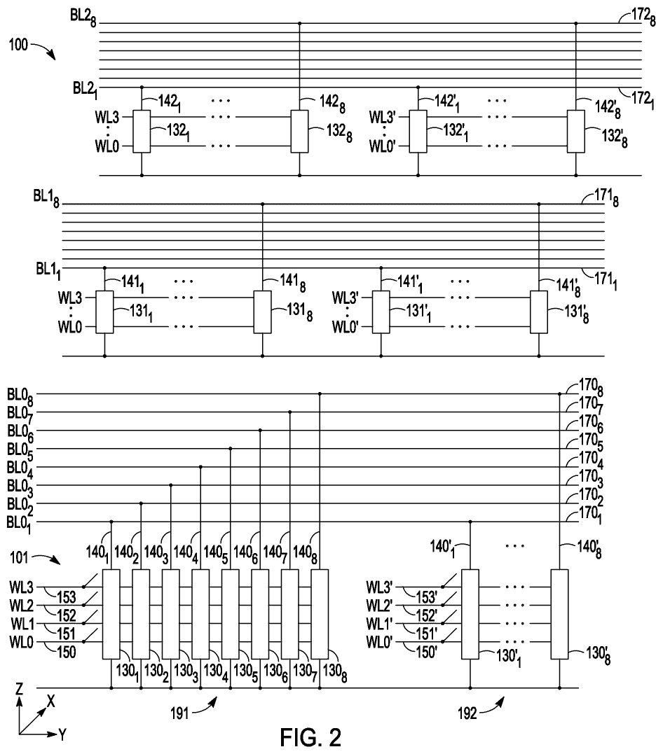

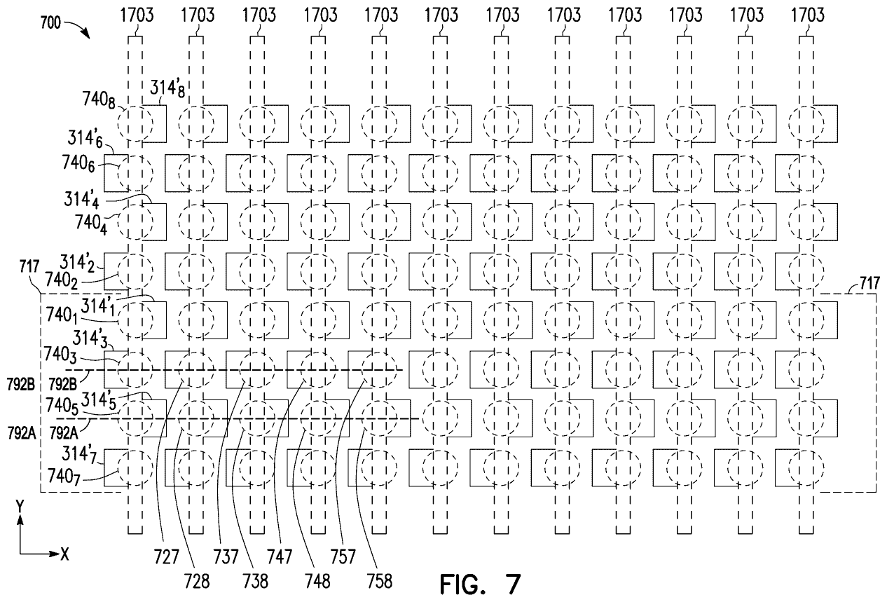

Memory device 100 includes other components, which are not shown in FIG. 1 so as not to obscure the example embodiments described herein. Some of the structure of memory device 100 is described below with reference to FIG. 2 through FIG. 6. At least a portion of memory device 100 (e.g., a portion of memory cell area 101 and the sets of data lines 170₁ through 170_{N}, 171₁ through 171_{N}, and 172₁ through 172_{N}) can include structures that can be similar to (or the same as) any of the memory devices described below with reference to FIG. 7 through FIG. 52C.

FIG. 2 shows a schematic diagram of a portion of memory device 100 of FIG. 1 including an example where memory device 100 includes eight data lines (e.g., N=8) in each set of data lines, according to an embodiment of the invention. In FIG. 1 and FIG. 2, similar or identical elements are given the same labels. As shown in FIG. 2, memory device 100 can include a set of eight data lines 170₁ through 170₈ (170₁, 170₂, 170₃, 170₄, 170₅, 170₆, 170₇, and 170₈), a set of eight data lines 171₁ through 171₈, and a set of eight data lines 172₁ through 172₈.

As described above, the number of memory strings in the X-direction that are coupled to a set of data lines can be equal to the number (e.g., N) of data lines of the set of data lines. Thus, in the example of FIG. 2, each of blocks 191 and 192 can include eight memory strings in the X-direction that are coupled to a respective set of data lines. For example, in block 191, memory device 100 can include eight memory cell strings 130₁ through 130₈ (130₁, 130₂, 130₃, 130₄, 130₅, 130₆, 130₇, and 130₈) coupled to data lines 170₁ through 170₈, respectively; eight memory cell strings 1311 through 131₈ coupled to data lines 171₁ through 171₈, respectively; and eight memory cell strings 132₁ through 132₈ coupled to data lines 172₁ through 172₈, respectively.

In a similar fashion in block 192, memory device 100 can include eight memory cell strings 130′₁ through 130′₈ coupled to data lines 170₁ through 170₈, respectively; eight memory cell strings 131′₁ through 131′₈ coupled to data lines 171₁ through 171₈, respectively; and eight memory cell strings 132′₁ through 132′₈ coupled to data lines 172₁ through 172₈, respectively.

As shown in FIG. 2, memory cell strings 130₁ through 130₈ can be coupled to data lines 170₁ through 170₈ through conductive connections 140₁ through 140₈, respectively. Memory cell strings 130′₁ through 130′₈ can be coupled to data lines 170₁ through 170₈ through conductive connections 140′₁ through 140₈′, respectively.

In similar connections, memory cell strings 131₁ through 131₈ can be coupled to data lines 171₁ through 171₈ through conductive connections 141₁ through 141₈, respectively. Memory cell strings 131′₁ through 131′₈ can be coupled to data lines 171₁ through 171₈ through conductive connections 141′₁ through 141₈′, respectively.

Memory cell strings 132₁ through 132₈ can be coupled to data lines 172₁ through 172₈ through conductive connections 142₁ through 142₈, respectively. Memory cell strings 132′₁ through 132′₈ can be coupled to data lines 172₁ through 172₈ through conductive connections 142′₁ through 142₈′, respectively.

The memory cell strings in the X-direction in one block (e.g., block 191) can be coupled to a particular set of data lines in the same way that memory cell strings in the X-direction in another block (e.g., block 191) are coupled to that particular set of data lines. For example, as shown in FIG. 2, memory cell strings 130₁ through 130₈ in block 191 can be coupled (e.g., coupled in a sequential order) to data lines 170₁ through 170₈ in the same way that memory cell strings 130′₁ through 130′₈ in block 192 are coupled (e.g., coupled in a sequential order) to data lines 170₁ through 170₈. Thus, in a physical structure of memory device 100, conductive connections 140₁ through 140₈ can have similar (or the same) structures as conductive connections 141₁ through 141₈.

FIG. 2 shows example connections (e.g., sequential connections) between memory cell strings in the X-direction (e.g., memory cell strings 131′₁ through 131′₈) and a respective set of data lines (data lines 171₁ through 171₈). However, the connections between memory cell strings in the X-direction and a respective set of data lines can be different from the example connections shown in FIG. 2, as long as one memory cell string in the X-direction can be coupled to a respective data line of a set of data lines. For example, FIG. 2 shows that memory cell strings 130₁, 130₂, 130₃, 130₄, 1305, 130₆, 130₇, and 130₈ are coupled to data lines 170₁, 170₂, 170₃, 170₄, 170₅, 170₆, 170₇, and 170₈, respectively. However, memory cell strings 130₁ through 130₈ can be coupled to data lines 170₁ through 170₈ in a different way (e.g., not in a sequential order shown in FIG. 2), as long as memory cell strings 130₁ through 130₈ and data lines 170₁ through 170₈ can be coupled to each other in a one-to-one connection (e.g., memory cell strings 130₁ through 130₈ do not share data lines 170₁ through 170₈).

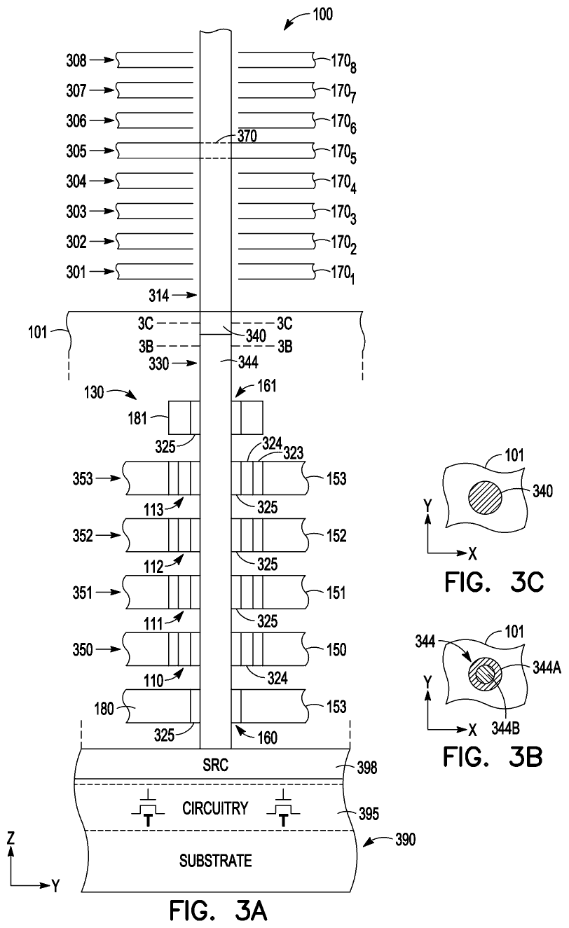

FIG. 3A shows a side view (e.g., a cross section with respect to the Z-Y directions) of a structure of a portion of memory device 100 of FIG. 2 including the structure of data lines 170₁ through 170₈ and a structure of a memory cell string 130 of memory device 100, according to some embodiments described herein. For simplicity, detailed description of the same element is not repeated from one figure to the next. Also for simplicity, cross-sectional lines (e.g., hatch lines) are omitted from most of the elements shown in the drawings described herein. Some elements of memory device 100 and other memory devices (e.g., memory device 700) described herein may be omitted from a particular figure of the drawings so as to not obscure the description of the element (or elements) being described in that particular figure. The dimensions (e.g., physical structures) of the elements shown in the drawings described herein are not scaled.

In FIG. 3A, the structure of memory cell string 130 can be the structure of one of memory cell strings 130₁ through 130₈ of block 191 of memory device 100. Other memory cell strings (FIG. 1 and FIG. 2) of memory device 100 can have a structure similar to (or the same as) the structure of memory cell string 130.

As shown in FIG. 3A, data lines 170₁ through 170₈ can have respective lengths extending in the Y-direction. Each of data lines 170₁ through 170₈ can have a thickness (which is less than the length) in the Z-direction. Data lines 170₁ through 170₈ and be located (e.g., stacked over one another) in different levels (e.g., layers) 301 through 308, respectively, of memory device 100. As shown in FIG. 3A, levels 301 through 308 are located in a portion of memory device 100 that is over (with respect to the Z-direction) memory cell area 101. Memory cell area 101 is located over a substrate 390 of memory device 100. As described above with reference to FIG. 1, memory cell area 101 is where the memory cell strings (one of which is shown as memory cell string 130) of memory device 100 can be formed.

In FIG. 3A, a conductive structure 314 can be part of one of conductive connections 140₁ through 140₈ (FIG. 2) of memory device 100. Conductive structure 314 can include (e.g., can be formed from) a conductive material (e.g., metal, conductively doped polysilicon, or other conductive materials). Conductive structure 314 can have a structure (e.g., vertical structure) of material that extends in the Z-direction through levels 301 through 308. Conductive structure 314 can be electrically coupled to (e.g., can contact) one of data lines 170₁ through 170₈ and electrically separated from (e.g., not contacting) the rest of data lines 170₁ through 170₈. For example, as shown in FIG. 3A, conductive structure 314 can be electrically coupled to data line 170₅ at a portion (e.g., a bridge) 370 of data line 170₅. FIG. 3A shows a separation (e.g., a gap) between conductive structure 314 and each of data lines 170₁ through 170₄ and data lines 170₆ through 170₈ (except data line 170₅) to indicate that conductive structure 314 is electrically separated from data lines 170₁ through 170₄ and data lines 170₆ through 170₈.

FIG. 3A shows conductive structure 314 being coupled to data line 170₅ as an example. However, conductive structure 314 can be coupled to a different data line among data lines 170₁ and 170₈, as long as conductive structure 314 is electrically coupled to at most one (only one) data of a set of data lines (e.g., coupled to only one of data lines 170₁ through 170₈).

As shown in FIG. 3A, memory cell string 130 can include a pillar (e.g., a vertical pillar) 330. Pillar 330 can include (e.g., can be formed from) a conductive material (e.g., conductively doped polysilicon). As shown in FIG. 3A, pillar 330 can have a length that extends in the Z-direction (e.g., extends vertically with respect to substrate 390). The memory strings (e.g., memory cell strings 130 through 130₈ in FIG. 1) of memory device 100 can include respective pillars each of which can be similar to (or the same as) pillar 330.

Memory cell string 130 can include a conductive contact 340, which can be part of pillar 330 of memory cell string 130. Conductive contact 340 can be formed from metal or other conductive material. Pillar 330 can include a portion 344. Conductive contact 340 and portion 344 of pillar 330 can include the same conductive material or different conductive materials.

Conductive structure 314 and pillar 330 can be part of a circuit path (e.g., a conductive channel of memory cell string 130) between data line 170₅ and a conductive region 398 (associated with signal SRC). Conductive region 398 can be part of line (e.g., source line or source plate) 198 in FIG. 1. In FIG. 3A, during a memory operation (e.g., read or write operation) of memory device 100, a circuit path (e.g., a current path) can be formed between data line 170₅ and conductive region 398 through conductive structure 314 and pillar 330.

As shown in FIG. 3A, conductive contact 340 can be located at one side (e.g., drain side) of memory cell string 130 that is closer to the data lines (e.g., data lines 170₁ through 170₈) than another side (e.g., source side next to a conductive region 398). Thus, conductive contact 340 in FIG. 3A can be called drain contact of memory cell string 130.

Substrate 390 of memory device 100 can include a semiconductor substrate (e.g., silicon-based substrate). For example, substrate 390 can include a p-type silicon substrate or an n-type silicon substrate. As shown in FIG. 3A, memory cells 110, 111, 112, and 113 of memory cell string 130 can be located along respective portions of pillar 330 in different levels of memory device 100 in the Z-direction. For example, memory cells 110, 111, 112, and 113 can be located one over another (e.g., formed vertically) in levels 350, 351, 352, and 353, respectively.

Control gates 150, 151, 152, and 153 can be located along respective portions (in the Z-direction) of pillar 330 in the same levels (e.g., levels 350, 351, 352, and 353, respectively) that memory cells 110, 111, 112, and 113 are located. Control gates 150, 151, 152, and 153 can include (e.g., can be formed form) a conductive material (e.g., metal, doped polysilicon, other conductive materials).

In FIG. 3A, select gate 180 is the same select gate 180 shown in FIG. 1. Select gate 181 in FIG. 3A can be one of select gates 181₁ through 181_{N} (FIG. 1). Transistor 161 can be one of transistors 161₁ through 161_{N} of FIG. 1. As shown in FIG. 3A, transistors 160 and 161 can be located along respective portions of pillar 330 in the Z-direction. The materials of select gates 180 and 181 can include a conductive material (e.g., conductively doped polysilicon, metal, other conductive material).

Memory cell string 130 can include materials 323, 324, 325 between portion 344 of pillar 330 and a respective control gate among control gates 150, 151, 152, and 153. Material 325 can also be between pillar 330 and each of select gates 180 and 181. As shown in FIG. 3A, materials 323, 324, 325 can be separated among memory cells 110, 111, 112, and 113. Materials 323, 324, 325 located at a particular memory cell (among memory cells 110, 111, 112, and 113) can be part (e.g., a memory element) of that particular memory cell.

Material 323 can include a charge blocking material (or charge blocking materials), for example, a dielectric material (e.g., silicon dioxide) that is capable of blocking a tunneling of a charge.

Material 324 can include a charge storage material (or charge storage materials) that can provide a charge storage function to represent a value of information stored in memory cell 310, 311, 312, and 313. For example, material 324 can include polysilicon (e.g., conductively doped polysilicon), which can be either a p-type polysilicon or an n-type polysilicon. The polysilicon can be configured to operate as a floating gate (e.g., to store charge) in a memory cell (e.g., a memory cell 110, 111, 112, or 113). In another example, material 324 can include a dielectric material (e.g., silicon-nitride based material or other dielectric materials) that can trap charge in a memory cell (e.g., a memory cell 110, 111, 112, or 113).

Material 325 can include a tunnel dielectric material (or tunnel dielectric materials), for example, silicon oxynitride, that is capable of allowing tunneling of a charge (e.g., electrons).

As shown in FIG. 3A, memory device 100 can include circuitry 395 located (e.g., formed) under memory cell area 101 (e.g., located directly under memory cell string 130). Circuitry 395 can include circuit elements (e.g., transistors T) coupled to other circuit elements (e.g., coupled to data lines 170₁ through 170₈) of memory device 100. The circuit elements (e.g., transistors T) of circuitry 395 can be configured to perform part of a function of a memory device (e.g., memory device 100). For example, circuitry 395 can include decoder circuits, driver circuits, buffers, sense amplifiers, charge pumps, and other circuitry of memory device 100.

Different views of pillar 330 along lines 3B-3B and 3C-3C are shown in FIG. 3B and FIG. 3C, respectively. FIG. 3B shows a top view (e.g., a cross section with respect to the X-Y plane) of portion 344 of pillar 330 along line 3B-3B of FIG. 3A. FIG. 3C shows a top view (e.g., a cross section with respect to the X-Y plane) of conductive contact 340 of pillar 330 along line 3C-3C of FIG. 3A.

As shown in FIG. 3B, portion 344 can include material 344A and material 344B surrounded by material 344A. Material 344A can be (or can include) part of a conductive structure (e.g., a conductive channel) of pillar 330. Material 344B can include a dielectric material. In an alternative structure of pillar 330, material 344B can omitted from pillar 330, such that the entire portion 344 of pillar 330 can include material 344A (without material 344B).

As shown in FIG. 3C, the shape of conductive contact 340 (e.g., in a top view) can be relatively circular. Similarly, in FIG. 3B, the shape of portion 344 (e.g., in a top view) can be relatively circular. Other conductive contacts (e.g., drain contacts) of memory cell strings (shown in FIG. 1 and FIG. 2) of memory device 100 can have a similar shape (from a top view) as the shape of conductive contact 340.

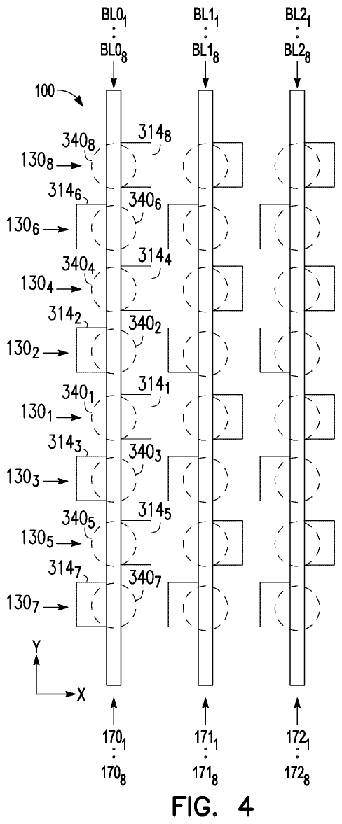

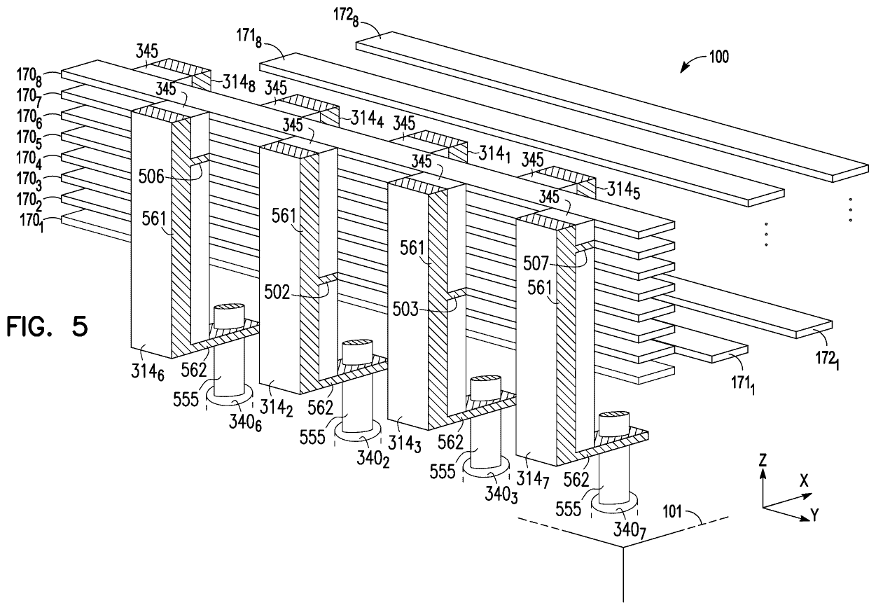

FIG. 4 shows a top view of a structure of memory device 100 including data lines 170₁ through 170₈, 171₁ through 171₈, and 172₁ through 172₈, and conductive contacts (e.g., drain contacts)3401 through 340₈ of respective memory cell strings 130₁ through 130₈ of memory device 100, according to some embodiments described herein. Conductive contacts 340₁ through 340₈ are located under (in the Z-direction) respective stacks of data lines 170₁ through 170₈. As shown in FIG. 4, data lines 170₁ through 170₈, data lines 171₁ through 171₈, and data lines 172₁ through 172₈ can have lengths extending in the Y-direction. For simplicity, other conductive contacts (and memory cell strings) associated with data lines 171₁ through 171₈ and 172₁ through 172₈ are not labeled. As shown in FIG. 4, each of conductive contacts 340₁ through 340₈ can have a shape (from a top view) similar to the shape (e.g., circular) of conductive contact 340 of pillar 330 of memory cell string 130 in FIG. 3A, FIG. 3B, and FIG. 3C. Conductive contacts 340₁ through 340₈ can be located along the lengths (in the Y-direction) and on both sides (in the X-directions) of the stack of data lines 170₁ through 170₈.

FIG. 4 also shows conductive structures 314₁ through 314₈ and other conductive structures (not labeled) of memory device 100. As shown in FIG. 4, conductive structures 314₁ through 314₈ can be alternatively formed on the sides (e.g., left and right sides in the X-direction) of the stack of data lines 171₁ through 171₈.

Each of the conductive structures (e.g., conductive structure 314₁ through 314₈) can contact (e.g., electrically couple to) a respective conductive contact. For example, conductive structure 314₁ can contact conductive contact 340₁, conductive structure 314₂ can contact conductive contact 340₂, and so on.

As shown in FIG. 4, each of the conductive structures (e.g., conductive structures 314₁ through 314₈) can also contact (e.g., electrically couple to) a respective data line of a stack of data lines at a portion (e.g., a bridge) of the respective data line. Such a portion can be a protrusion portion of the respective data line. For example, as shown in FIG. 5, conductive structure 314₇ can contact data line 170₇ at a portion 507 that can be a protrusion portion (e.g., an integral part) of data line 170₇.

As described above with reference to FIG. 2 and FIG. 3, memory device 100 can have example of eight data lines (e.g., N=8) in each set of data lines. As shown in FIG. 4 and FIG. 5, the set of data lines 170₁ through 170₈ (associated with signals BL0₁ through BL0₈) can be formed in a stack of eight data lines that are stacked in the Z-direction one over another. As shown in FIG. 4 and FIG. 5, data line 170₈ can be the topmost data line and data lines 170₁ through 170₇ can be under (below in the Z-direction) data line 170₈. In FIG. 4, data lines 170₁ through 170₇ are hidden under data line 170₈.

In a similar formation, the set of data lines 171₁ through 171₈ (associated signals BL1₁ through BL1₈) can be formed in a stack of eight data lines that are stacked in the Z-direction one over another. For example, as shown in FIG. 4, data line 171₈ can be the topmost data line and data lines 171₁ through 171₇ (which are hidden under data line 171₈) can be under (below in the Z-direction) data line 171₈.

The set of data lines 172₁ through 172₈ (associated with signals BL2₁ through BL2₈) can be formed in a stack of eight data lines that are stacked in the Z-direction one over another. For example, as shown in FIG. 4, data line 172₈ can be the topmost data line and data lines 172₁ through 172₇ (which are hidden under data line 172₈) can be under (below in the Z-direction) data line 172₈.

FIG. 5 shows an isometric view of a portion of a structure of memory device 100 of FIG. 4 including memory cell area 101 and the stacks of data lines 170₁ through 170₈, 171₁ through 171₈, and 172₁ through 172₈, according to some embodiments described herein. As shown in FIG. 5, the set of data lines 170₁ through 170₈ can be formed in a stack of eight data lines. The set of data lines 171₁ through 171₈ can be formed in another stack of eight data lines (e.g., next to the stack of data lines 170₁ through 170₈). The set of data lines 172₁ through 172₈ can be formed in another stack of eight data lines (e.g., next to the stack of data lines 171₁ through 171₈). The stacks of data lines 170₁ through 170₈, 171₁ through 171₈, and 172₁ through 172₈ can be located side by side with each other (in the X-direction) and located on the same level of memory device 100.

As shown in FIG. 5, each of data lines 170₁ through 170₈ can include (e.g., can be formed from) a structure (e.g., a piece (e.g., a layer)) of conductive material. Thus, the set of data lines 170₁ through 170₈ can include eight separated structures (e.g., pieces) of material stacked one over another over memory cell area 101. In a similar formation, the set of data lines 171₁ through 171₈ can be formed in another stack of eight structures (e.g., pieces (e.g., layers)) of conductive materials (e.g., next to the stack of data lines 170₁ through 170₈). The set of data lines 172₁ through 172₈ can be formed in another stack of eight structures (e.g., pieces (e.g., layers)) of conductive materials (e.g., next to the stack of data lines 171₁ through 171₈). Example materials for data lines 170₁ through 170₈, 171₁ through 171₈, and 172₁ through 172₈ include metal, conductively doped polysilicon, or other conductive materials.

FIG. 5 also shows some of the conductive contacts (e.g., conductive contacts 340₂, 340₃, 340₆, and 340₇) and corresponding conductive structures (e.g., conductive structures 314₂, 314₃, 314₆, and 314₇) of memory device 100 coupled to the conductive contacts. Conductive structures 314₂, 314₃, 314₆, and 314₇ and conductive portions 555 can be parts of conductive connections 140₁, 140₃, 140₅β, 140₇, and 140₈ that are schematically shown in FIG. 2, respectively, of memory device 100. As shown in FIG. 5, conductive structures 314₂, 314₃, 314₆, and 314₇ can be located on one side of the stack of data lines 170₁ through 170₈. Conductive structures 314₁, 314₄, 314₅, and 314₈ can be located on another side of the stack of data lines 170₁ through 170₈. For simplicity, FIG. 5 omits the conductive contacts and the conductive structures associated with the stack of data lines 171₁ through 171₈ and the stack of data lines 172₁ through 172₈.

As shown in FIG. 5, conductive structures 314₂, 314₃, 314₆, and 314₇ can be coupled to respective data lines 170₂, 170₃, 170₆, and 170₇ at conductive portions (e.g., bridges) 502, 503, 506, and 507, respectively. Conductive portions 502, 503, 506, and 507 can be parts (e.g., integral parts) of data lines 170₂, 170₃, 170₆, and 170₇, respectively. Thus, the materials of conductive portions 502, 503, 506, and 507 can be the same as the materials of conductive structures 314₂, 314₃, 314₆, and 314₇, respectively. In FIG. 5, each of conductive portions 502, 503, 506, and 507 can be a protrusion portion of a respective data line in which the protrusion portion can protrude from a side of the respective data line in a direction (e.g., the X-direction) perpendicular to the length of the respective data line.

Each of the conductive structures (e.g., conductive structures 314₂, 314₃, 314₆, and 314₇) can include a portion (e.g., vertical conductive portion) 561 and a portion (e.g., horizontal conductive portion) 562. As shown in FIG. 5, portion 561 and portion 562 of a respective conductive structure (e.g., conductive structure 314₇) can form an L-shape. Portion 555 can extend through (in the Z-direction) portion 562, such that portion 562 can contact and surround at least a portion of conductive portion 555 at the location where conductive portion 555 contacts portion 562.

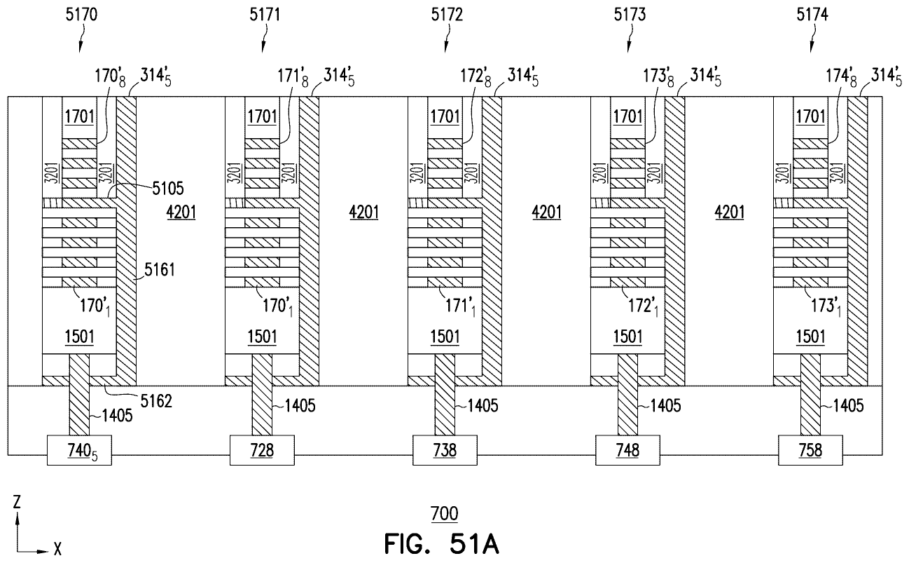

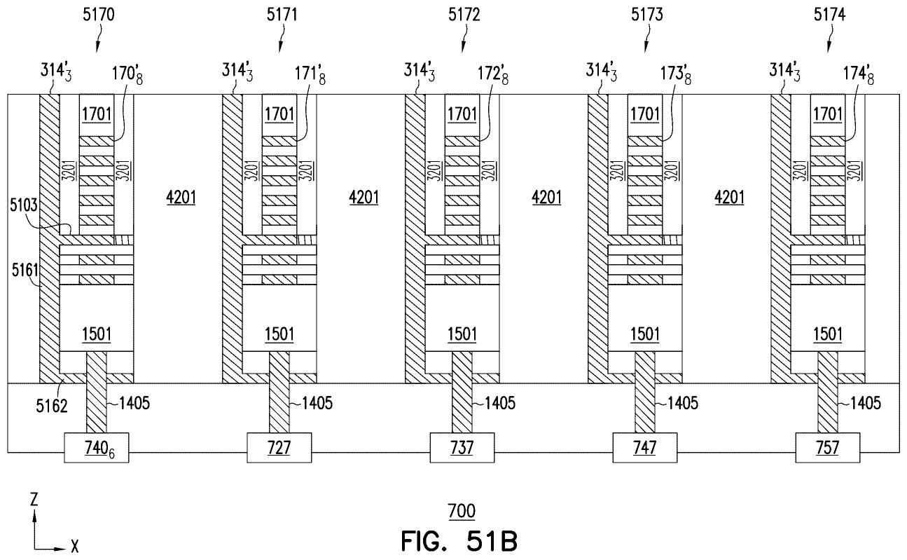

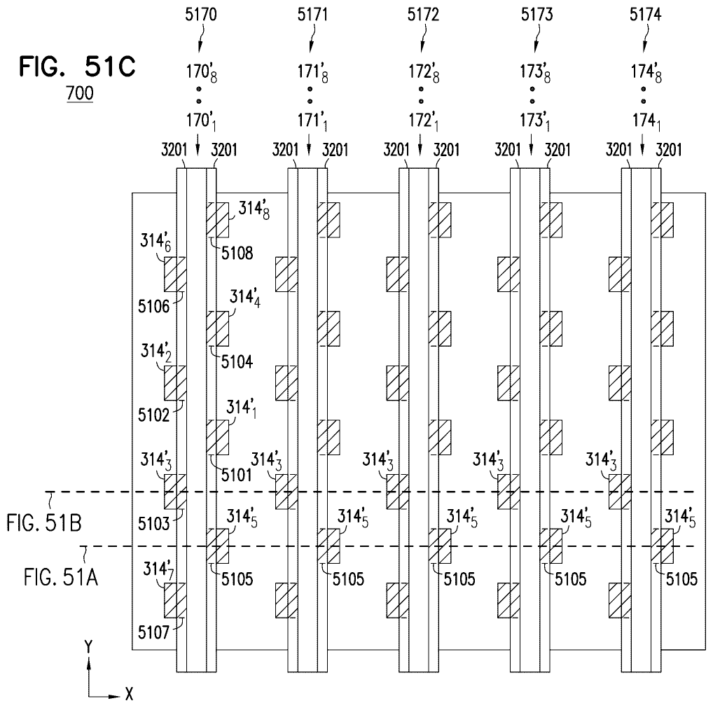

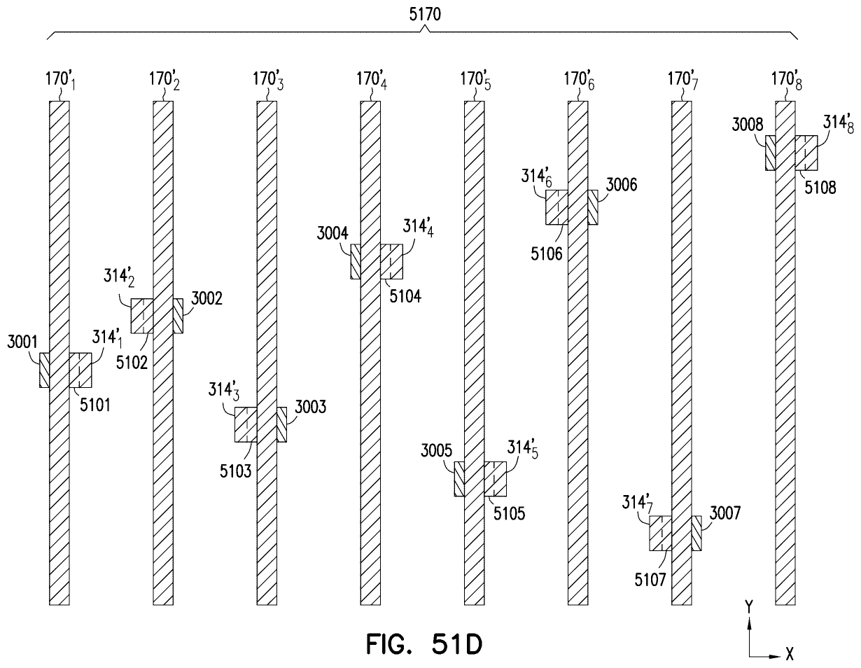

In a conductive structure (e.g., conductive structure 314₇), portion 561, portion 562, and the portion (one of portions 502, 503, 506, and 507) that couples portion 561 to the corresponding data line (e.g., data line 170₇) can have (e.g., can be formed from) the same conductive material (or materials) as that data line. In an example, portion 561 and portion 562 of conductive structure 314₇, portion 507, and the material of data line 170₇ can be formed in same process (e.g., formed in the same material deposition process), such that portion 561 and portion 562 of conductive structure 314₇, portion 507, and the material of data line 170₇ have the same conductive material (or materials) formed in that process (e.g., the process similar to that in FIG. 51A and FIG. 51B).

As shown in FIG. 5, conductive structures 314₂, 314₃, 314₆, and 314₇ can be coupled to respective conductive contacts 340₂, 340₃, 340₆, and 340₇ through conductive portions (vertical portions) 555.

As shown in FIG. 5, memory device 100 can include spacers (e.g., vertical dielectric spacers) 345. Spacers 345 can form dielectric structures that electrically separate respective conductive structures 314₁ through 314₈ from the stack of data lines 170₁ through 170₈.

As described above with reference to FIG. 1 through FIG. 5, the data lines (e.g., data lines 170₁ through 170₈) can be shared among the blocks (e.g., blocks 191 and 192 in FIG. 1 and FIG. 2). Thus, the stacks of data lines 170₁ through 170₈ in FIG. 5 can extend across (e.g., be formed over) the blocks of memory device 100 and can be coupled to respective conductive contacts (e.g., drain contacts) of respective memory cell strings in each of the blocks.

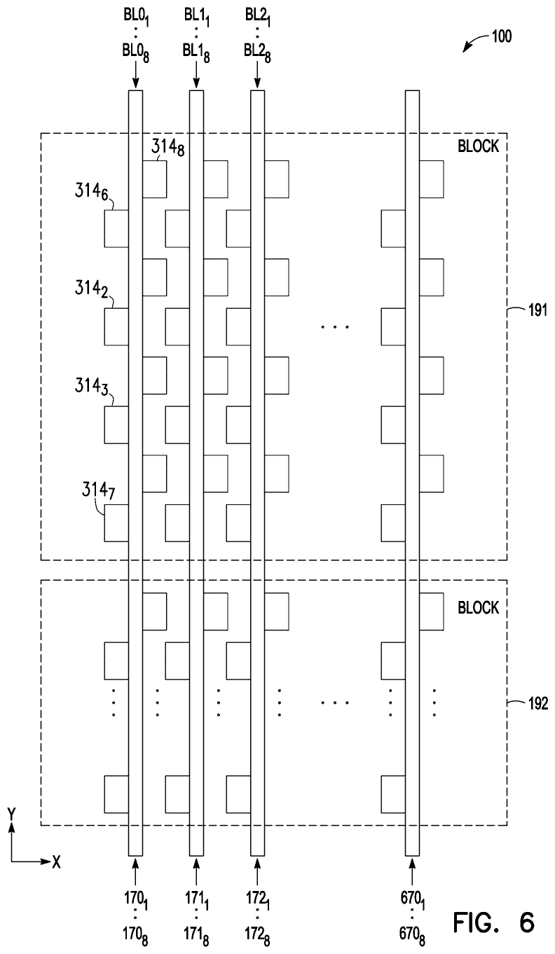

FIG. 6 shows a top view of a structure of memory device 100 including blocks 191 and 192 and the stacks of data lines 170₁ through 170₈, 171₁ through 171₈, and 172₁ through 172₈, according to some embodiments described herein. FIG. 6 also shows a stack of data lines 670₁ through 670₈ and conductive contacts (not labeled) along the stacks of data lines 670₁ through 670₈. For simplicity, FIG. 6 omits other stacks of data lines and conductive contacts between the stack of data lines 172₁ through 172₈ and the stack of data lines 670₁ through 670₈. For simplicity, only some of conductive structures (e.g., conductive structures 314₂, 314₃, 314₆, 314₇, and 314₈) are labeled in FIG. 6. As shown in FIG. 6, the stacks of data lines 170₁ through 170₈, 171₁ through 171₈, 172₁ through 172₈, and 670₁ through 670₈ can extend in the Y-direction across blocks 191 and 192.

The stack structure of the data lines of memory device 100 and other memory devices (e.g., memory device 700 described below with reference to FIG. 7 through FIG. 52C) allow the memory devices described herein to have improvements and benefits over some conventional memory devices. For example, the described stacked data lines (e.g., the stacks of data lines 170₁ through 170₈, 171₁ through 171₈, and 172₁ through 172₈ (FIG. 1 through FIG. 6) and the stacks of data lines in FIG. 7 through FIG. 52C) can increase the density of data lines for a given device area of the memory device (e.g., memory devices 100 and 700). This can allow more memory cells (e.g., more memory cell strings) for a given device area to be coupled to the stacked data lines, thereby increasing the memory cell density of the memory device for a given area.

Further, some conventional memory devices may have a spacing (e.g., horizontal spacing) constraint that limits the number of pillars of memory cell strings to be coupled to the data lines in such conventional memory devices. Therefore, some of the memory cell strings in such conventional memory devices may be unused (e.g., wasted). The stacked data lines described herein can remove such constraint and allow a relatively higher number of memory cell strings to be coupled to the stacked data lines. This can also increase the memory cell density for a given area of the described memory devices in comparison with some conventional memory devices.

Moreover, some applications may have a demand that includes a relatively higher number of memory cells for a specific device area. To accommodate such a demand, the pillar density (e.g., memory cell string density) for the specific device area of the memory device can be increased. Thus, the number of data lines may also increase. The stacked data lines described herein can allow data line density to keep pace with such pillar density (e.g., memory cell string density), thereby allowing the memory devices described herein to be suitable for such applications.

FIG. 7 through FIG. 52C show different views of elements during processes of forming a memory device 700, according to some embodiments described herein. Some or all of the processes used to form memory device 700 can be used to form memory device 100 described above with reference to FIG. 1 through FIG. 6.

FIG. 7 shows a top view of memory device 700 including conductive structures 314′₁ through 314′₈ that have been formed during some of the processes of forming memory device 700. Conductive structure 314′₁ through 314′₈ can correspond to conductive structures 314₁ through 314₈ (FIG. 4), respectively, of memory device 100. For simplicity, FIG. 7 omits labels for other conductive structures (which are similar to conductive structure 314′₁ through 314′₈) memory device 700.

FIG. 7 also shows conductive contacts 740₁ through 740₈ (which are coupled to respective conductive structure 314′₁ through 314′₈) and other conductive contacts 727, 737, 747, 757, 728, 738, 748, and 758 that also have been formed during some of the processes of forming memory device 700. For simplicity, FIG. 7 omits labels for other conductive contacts of memory device 700 shown in FIG. 7.

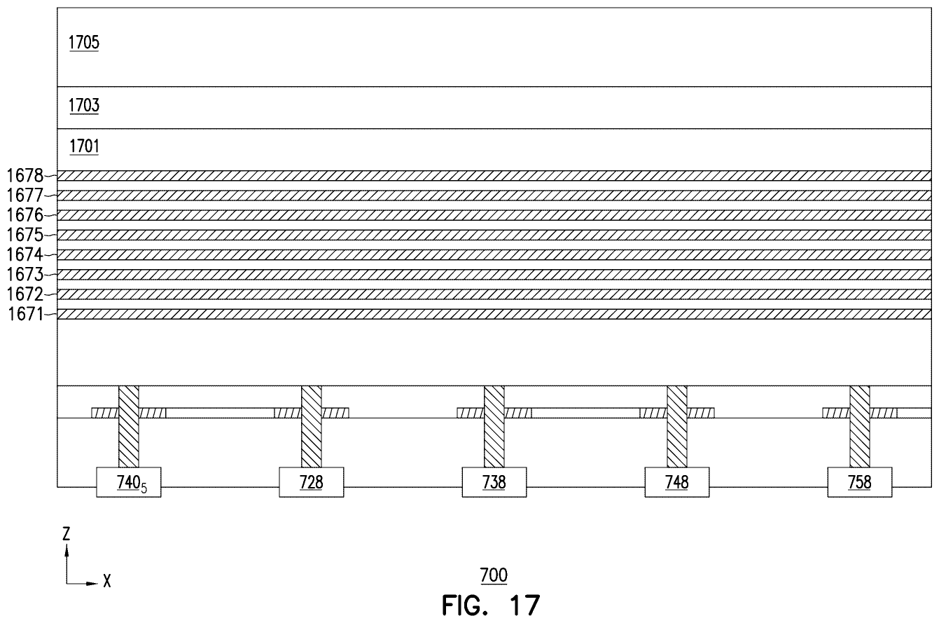

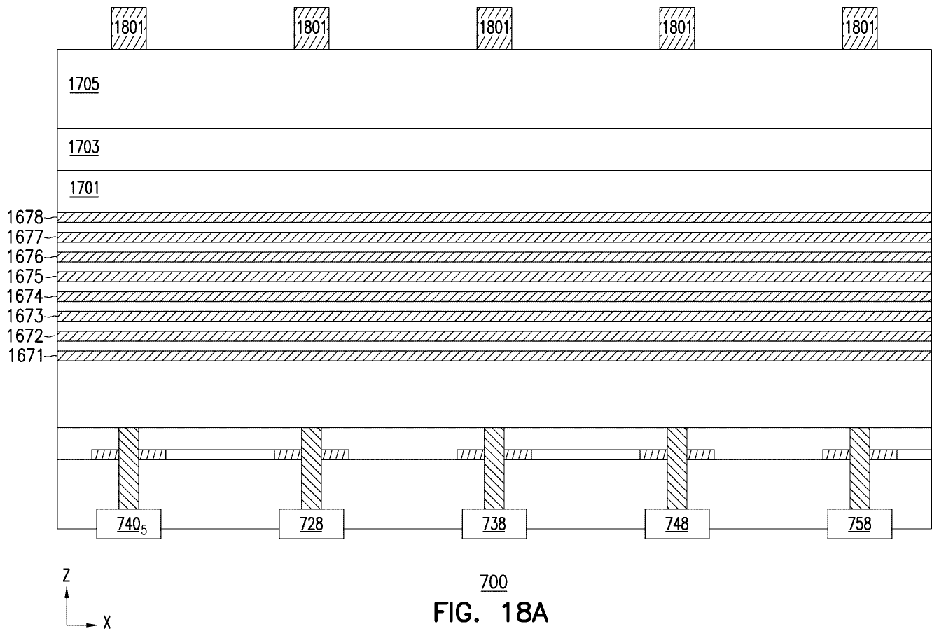

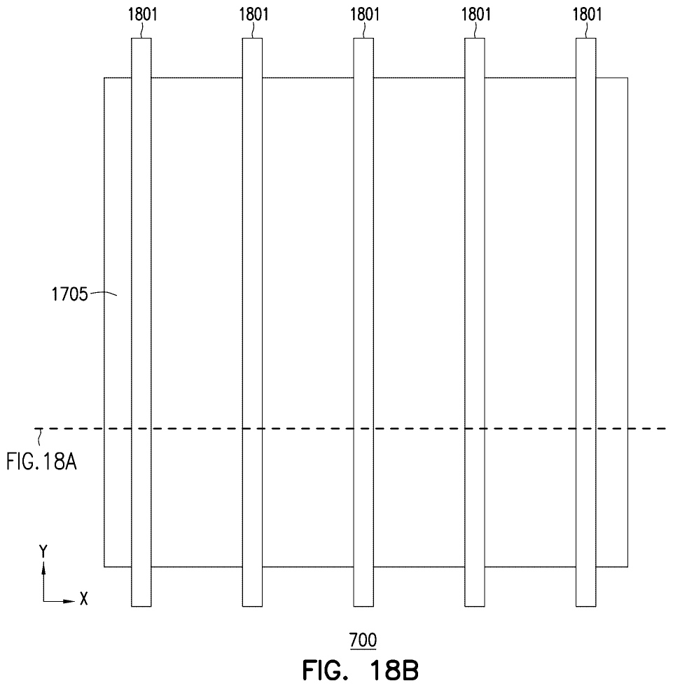

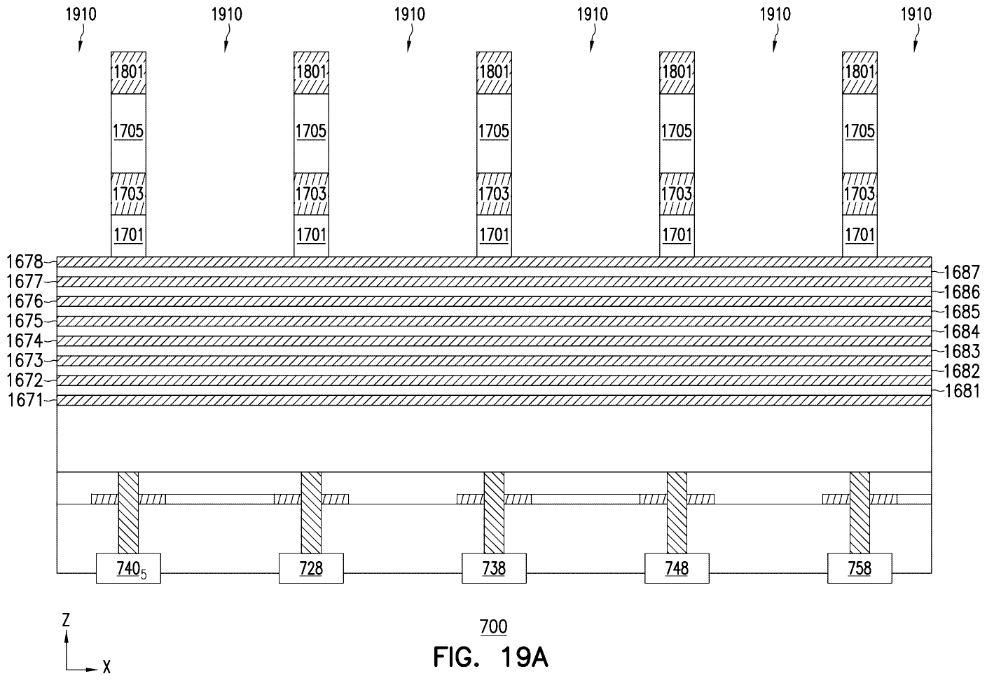

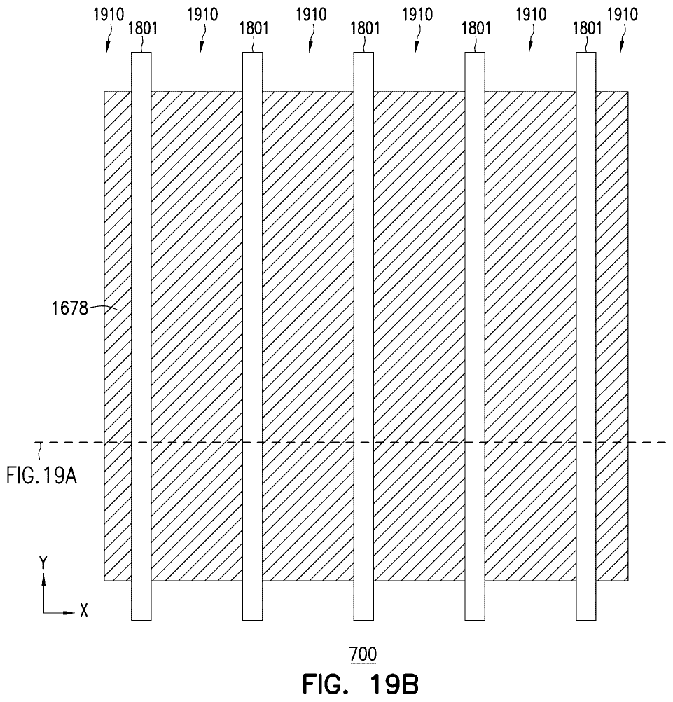

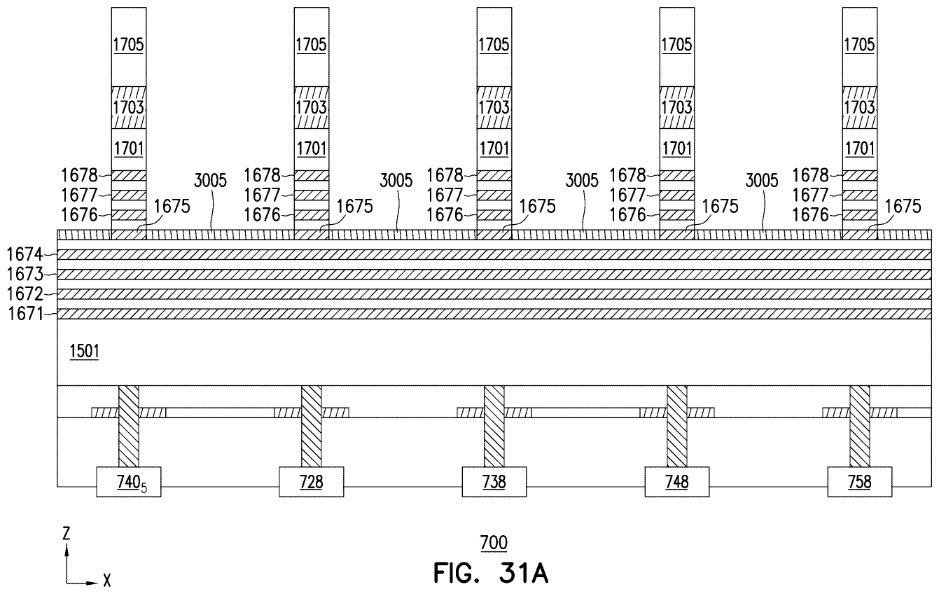

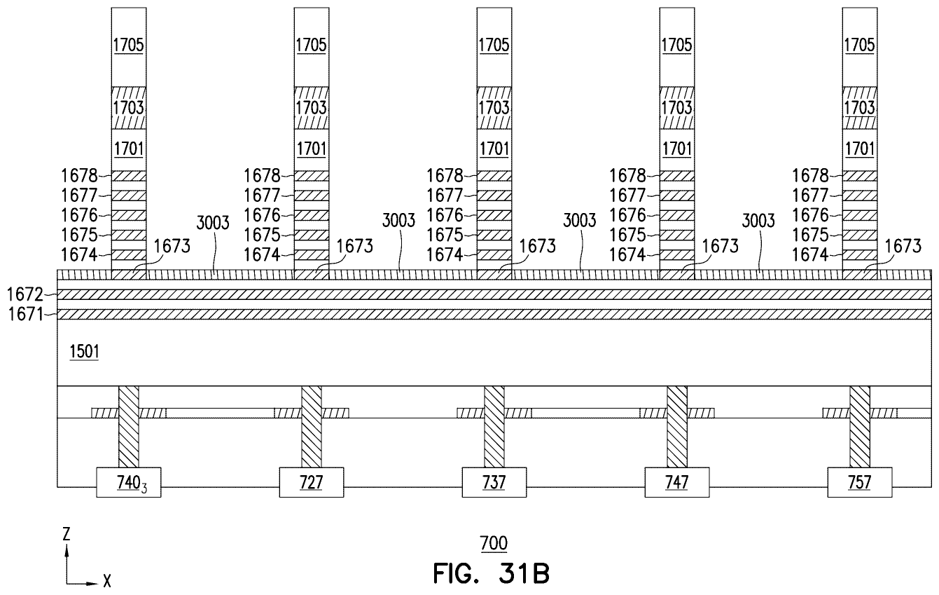

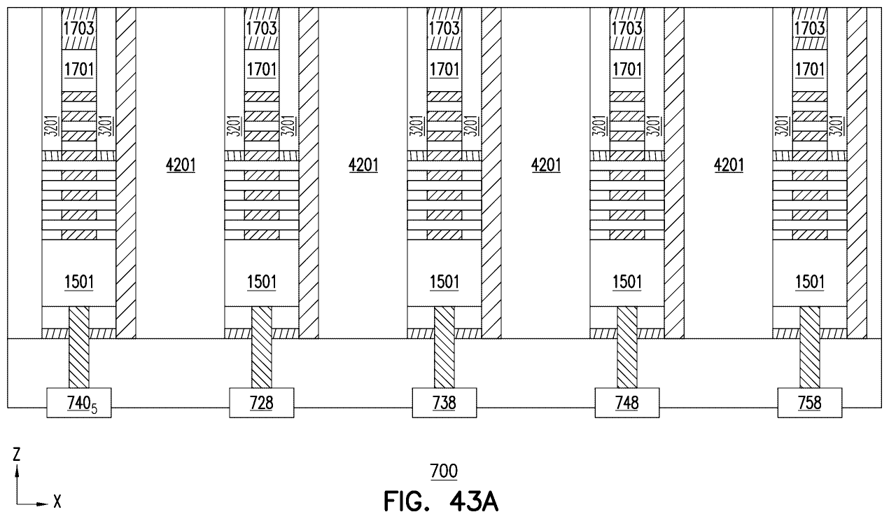

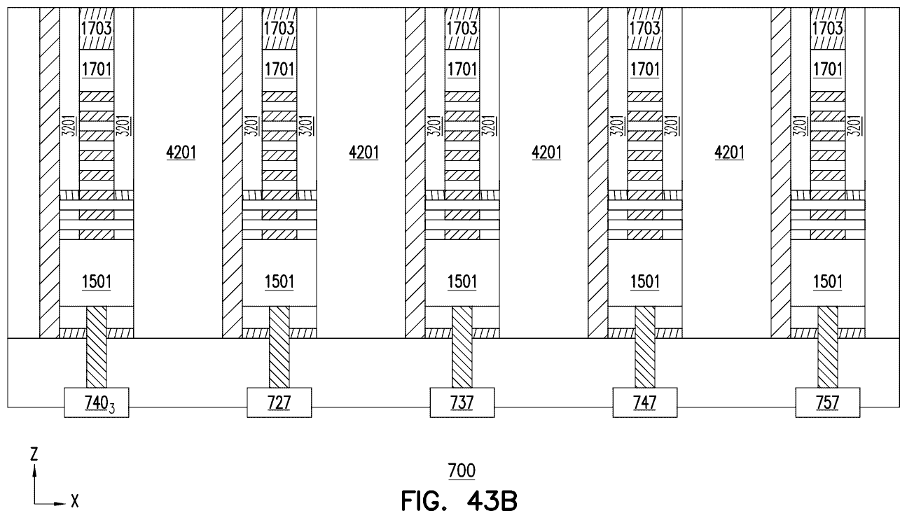

FIG. 7 also shows a material 1703 (which is formed in FIG. 17 and further processed in FIG. 31A and FIG. 43A). Each material 1703 can be formed to have length extending in the Y-direction and a width in X-direction. Material 1703 can be part of a mask structure. Material 1703 can include polysilicon other materials that can be impervious to processes (e.g., trimming and etching process) performed on other materials (e.g., silicon dioxide and silicon nitride) during formation of the stacks of data lines of memory device 700.

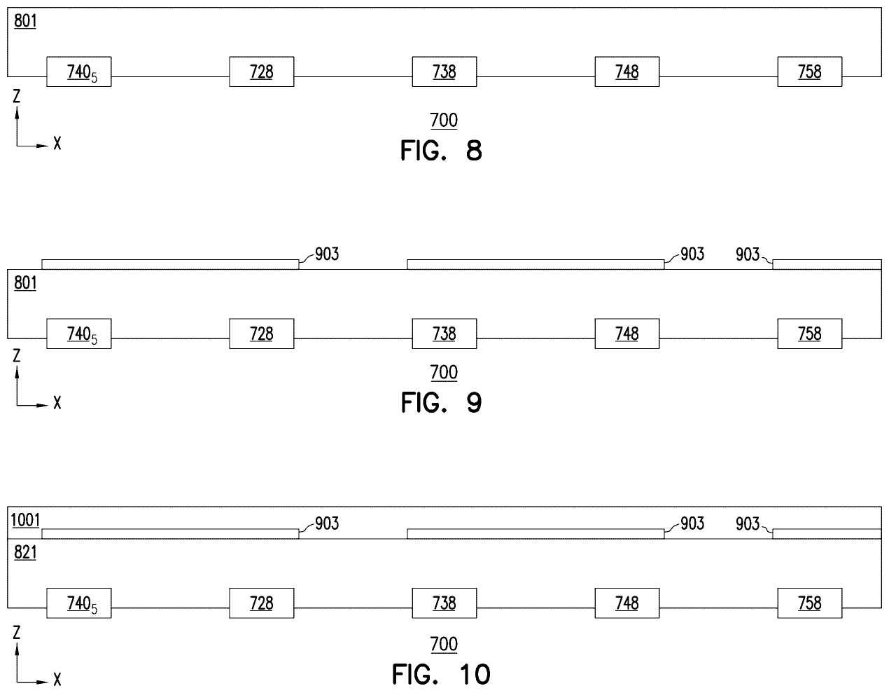

The processes of forming memory device 700 associated with FIG. 7 also form other materials (shown in FIG. 8) under material 1703. Lines 792A and line 792B in FIG. 7 show locations of memory device 700 where different views (e.g., cross sections) of memory device 700 are shown in subsequent figures.

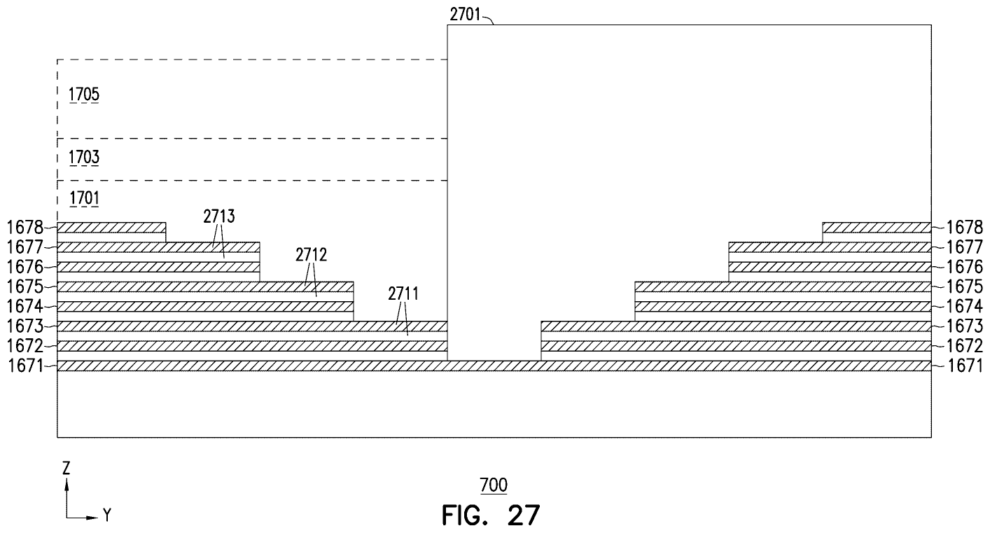

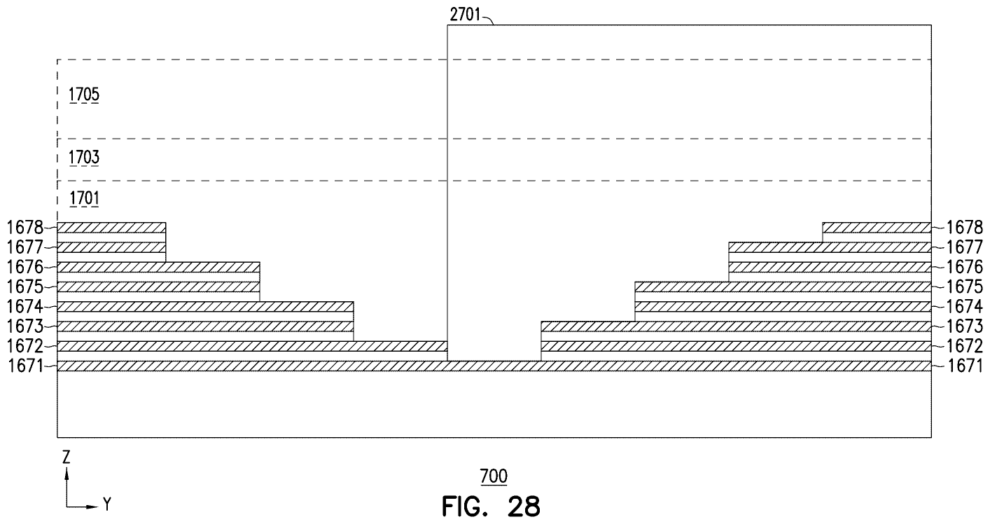

FIG. 7 also shows a location 717 (e.g., an area indicated by the dashed rectangular) that can span across part of memory device 700. As described below (e.g., with reference to FIG. 27 and FIG. 28), the processes of forming the stacks of data lines of memory device 700 can include forming a resist structure (e.g., resist structure 2701 in FIG. 27 and FIG. 28) at location 717 to cover the materials in a portion of memory device 700 (e.g., the portion under resist structure 2701 (FIG. 28) at location 717 shown in FIG. 7). A process described below with reference to FIG. 28 can selectively remove a portion of the materials that is not covered by the resist structure (e.g., resist structure 2701 in FIG. 28) at location 717 (FIG. 7). Such a process is part of forming staircase structures in the materials that are used to form the stacks of data lines of memory device 700.

FIG. 8 shows a portion (e.g., a cross section at line 792A in FIG. 7) of memory device 700 after the conductive contacts (e.g., conductive contacts 7405, 728, 738, 748, and 758) of memory device 700 are formed. Conductive contact 7405 can correspond to conductive contact 3405 of FIG. 4. FIG. 8 also shows a dielectric material (e.g., silicon dioxide) 801 formed over conductive contacts 7405, 728, 738, 748, and 758. Memory cell strings coupled to conductive contacts 7405, 728, 738, 748, and 758 are not shown in FIG. 8.

In FIG. 9, a dielectric material (e.g., silicon nitride) 903 is formed over dielectric material 801.

In FIG. 10, a dielectric material (e.g., silicon dioxide) 1001 is formed over dielectric material 903.

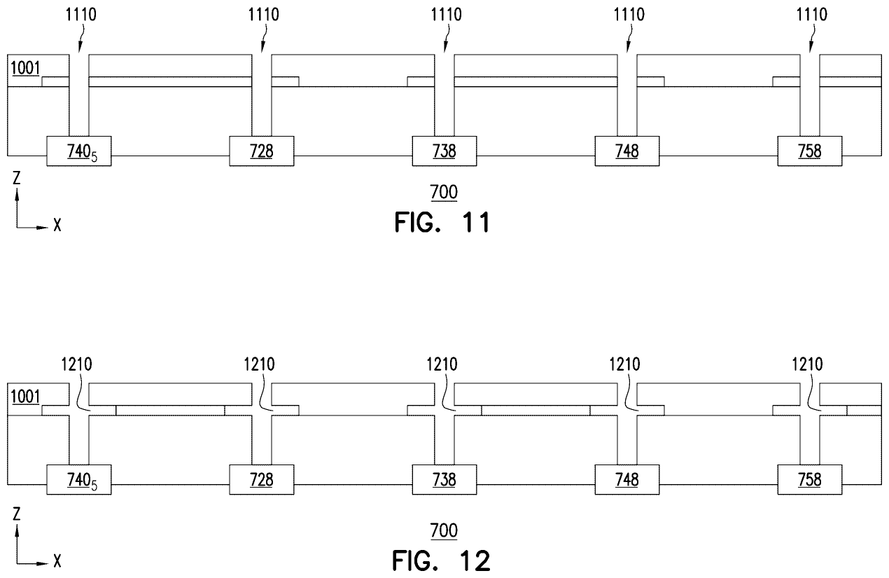

In FIG. 11, a portion of each of dielectric materials 801, 903, and 1001 are removed (e.g., patterned and etched) to form openings (e.g., holes) 1110 to expose conductive contacts 740₅, 728, 738, 748, and 758 at respective openings 1110.

In FIG. 12, cavities (e.g., recesses) 1210 are formed by removing (e.g., etching) at least part of each of dielectric material (e.g., silicon nitride) 903 (formed in FIG. 9).

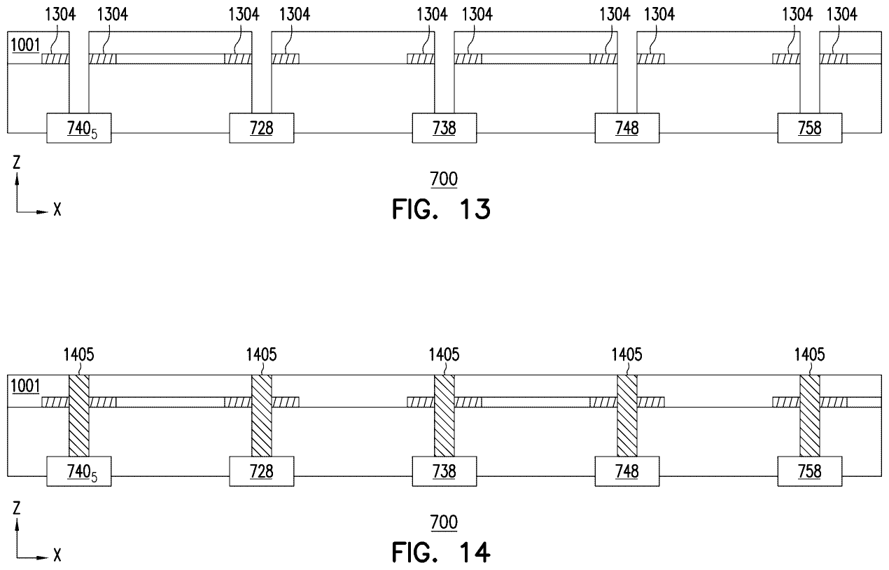

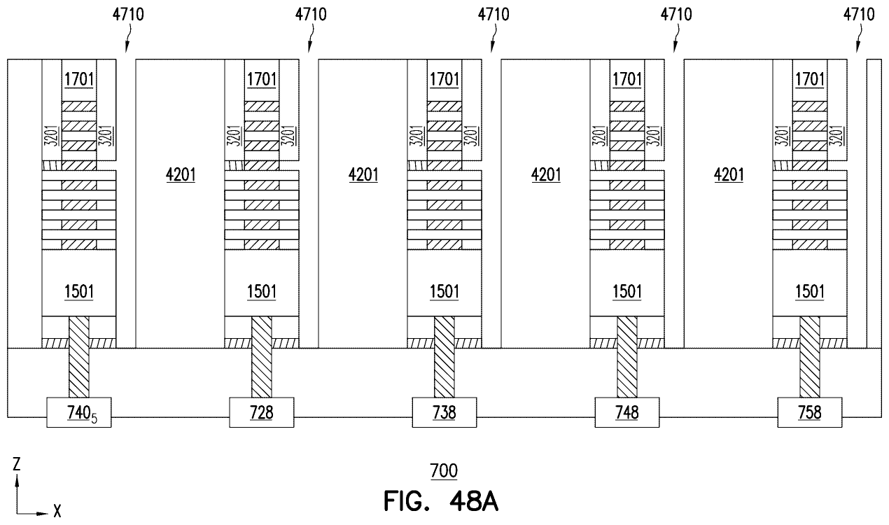

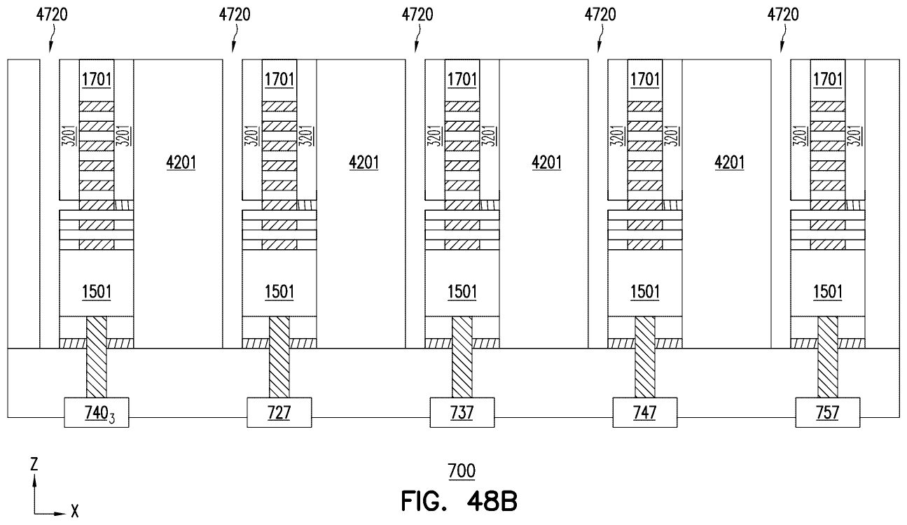

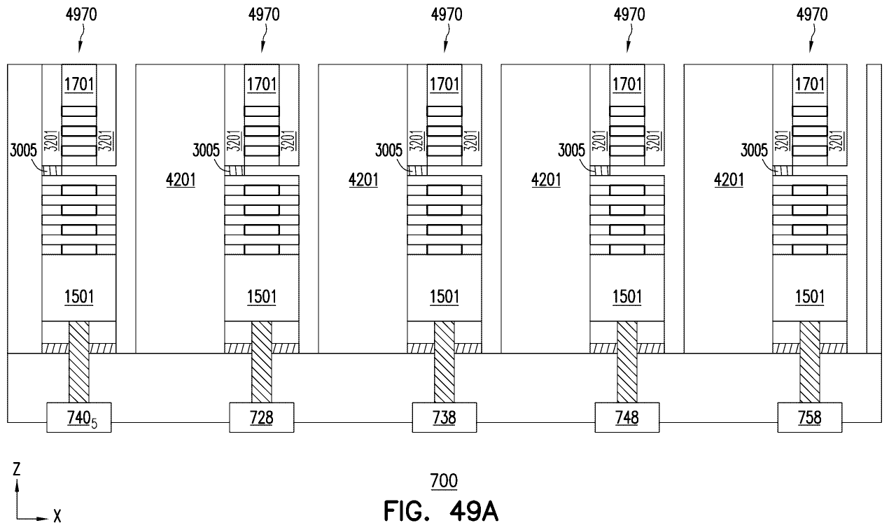

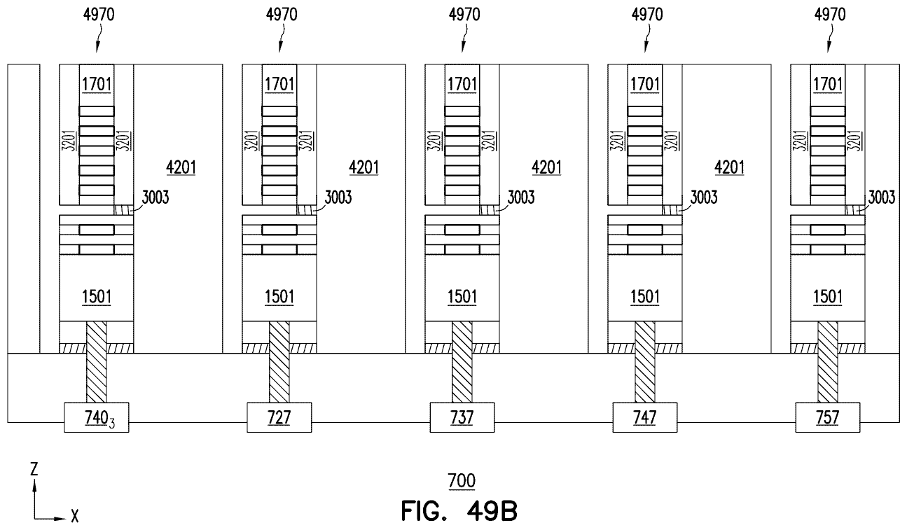

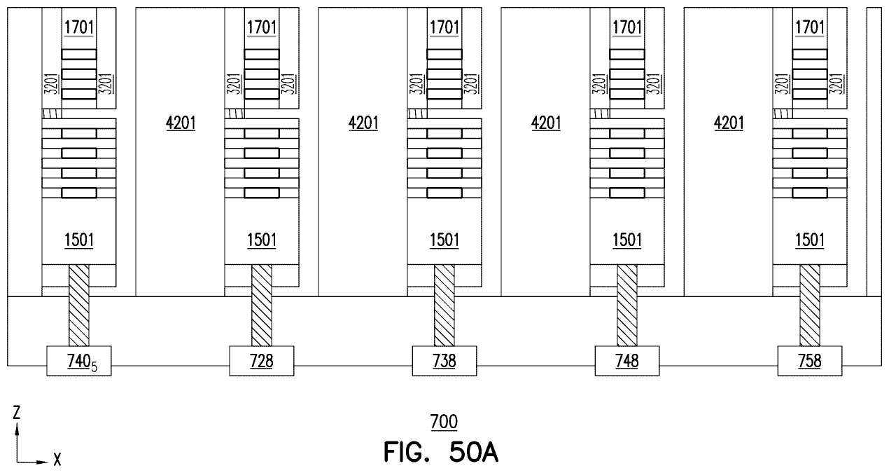

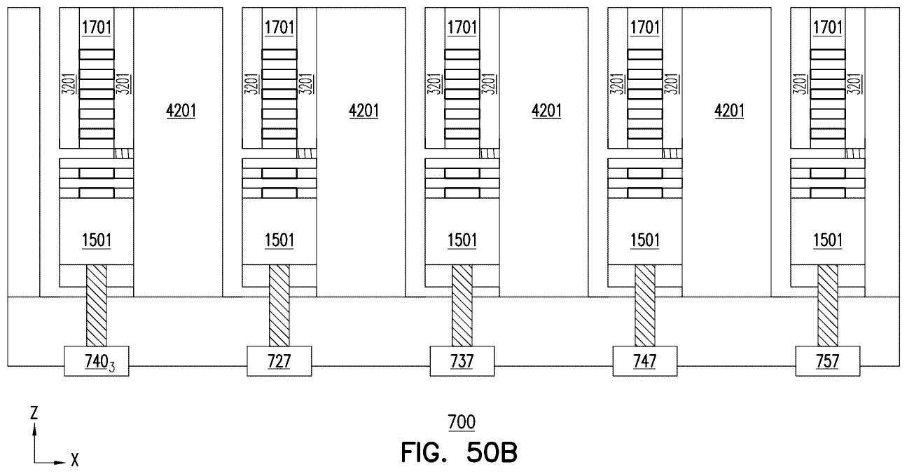

In FIG. 13, a material 130₄ is formed in cavities 1210. Material 130₄ can be a sacrificial material that will be removed in subsequent processes of forming memory device 700. In subsequent processes (e.g., FIG. 48A, FIG. 48B, FIG. 49A, and FIG. 49B) materials (e.g., silicon nitride) adjacent material 130₄ are moved (e.g., exhumed) without removing material 130₄ during such subsequent processes. Thus, material 130₄ can be selected such that it can withstand such subsequent processes (e.g., silicon nitride exhumed processes). Further, material 130₄ can be selected such that it can be selectively removed (e.g., in FIG. 50A and FIG. 50B) in relation to silicon dioxide (e.g., materials 1681 through 1687 (e.g., tier oxide)) and other conductive material (e.g., the material of conductive portion 1405 formed in FIG. 14). Examples of material 130₄ can include glass (e.g., borophosphosilicate glass BPSG), carbon nitride, or other suitable materials.

In FIG. 14, conductive portions 1405 are formed in openings 1110 (labeled in FIG. 11) and contacting conductive contacts 740₅, 728, 738, 748, and 758. Conductive portions 1405 can correspond to conductive portions 555 of memory device 100 of FIG. 5. Example materials for conductive portions 1405 can include tungsten (W) or a combination (e.g., layers) of conductive materials (e.g., Ti/TiN/W). The processes associated with FIG. 14 can include a material removal process (e.g., chemical mechanical planarization (CMP) process) to remove a portion (e.g., a top portion) of material 1001 and conductive portions 1405.

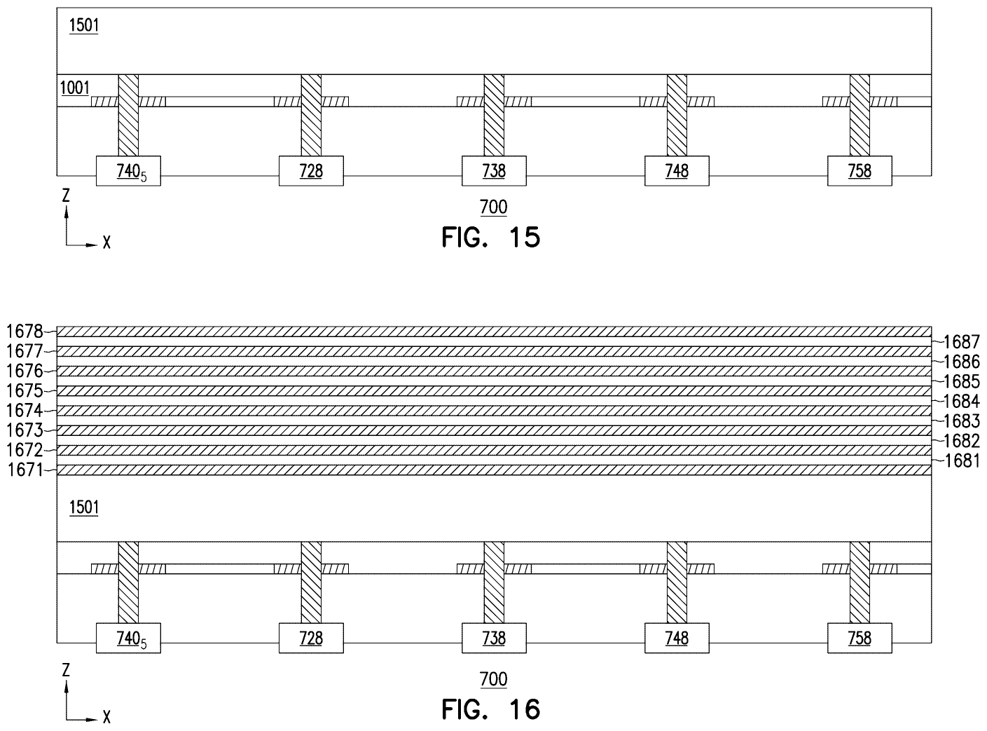

In FIG. 15, a dielectric material (e.g., silicon dioxide) 1501 is formed over dielectric material 1001 and conductive portion 1405.

In FIG. 16, different levels (e.g., layers) of materials are formed in respective levels (e.g., layers) of memory device 700 over dielectric material 1501. The different levels of materials formed by the process associated with FIG. 16 include materials 1671 through 1678 and materials 1681 through 1687. Materials 1671 through 1678 can include silicon nitride. Materials 1681 through 1687 can include silicon dioxide. Materials 1671 through 1678, and materials 1681 through 1687 can be formed in tiers in a sequential fashion one material after another over dielectric material 1501. For example, the processes used in FIG. 16 can include forming (e.g., depositing) material 1671 over dielectric material 1501, material 1681 over material 1671, forming (e.g., depositing) material 1672 over material 1681, forming (e.g., depositing) material 1682 over material 1672, and so on until material 1678 is formed. Materials 1671 through 1678 can be called tier nitrides. Materials 1681 through 1687 can be called tier oxide.

In FIG. 17, a dielectric material (e.g., silicon dioxide) 170₁, a material 1703, and a dielectric material (e.g., silicon dioxide) 170₅ are formed. Material 1703 can be a sacrificial material that will be removed in subsequent processes of forming memory device 700. An example for material 1703 includes polysilicon.

In FIG. 18A, material (e.g., pattern) 1801 is formed. Material 1801 can be used in a process (e.g., an etch process) to remove materials that are not under material 1801. FIG. 18B is a top view of memory device of FIG. 18A. In FIG. 18B, the line labeled FIG. 18A is the location of a cross-section of memory device 700 shown in FIG. 18A.

In FIG. 19A, a portion of each of dielectric material (e.g., silicon dioxide) 170₁, material (e.g., polysilicon) 1703, and dielectric material (e.g., silicon dioxide) 170₅ is removed from locations 1910 to expose material 1678.

FIG. 19B shows a top view of memory device 700 of FIG. 19A. The line labeled FIG. 19A in FIG. 19B is the location of a cross-section of memory device 700 shown in FIG. 19A. In FIG. 19A, material (e.g., polysilicon) 170₅ can be part of a mask structure (e.g., hard mask structure). In subsequent processes (e.g., etch processes) materials 1671 through 1678 and materials 1681 through 1687 under the mask structure (e.g., under material 1705) are not removed.

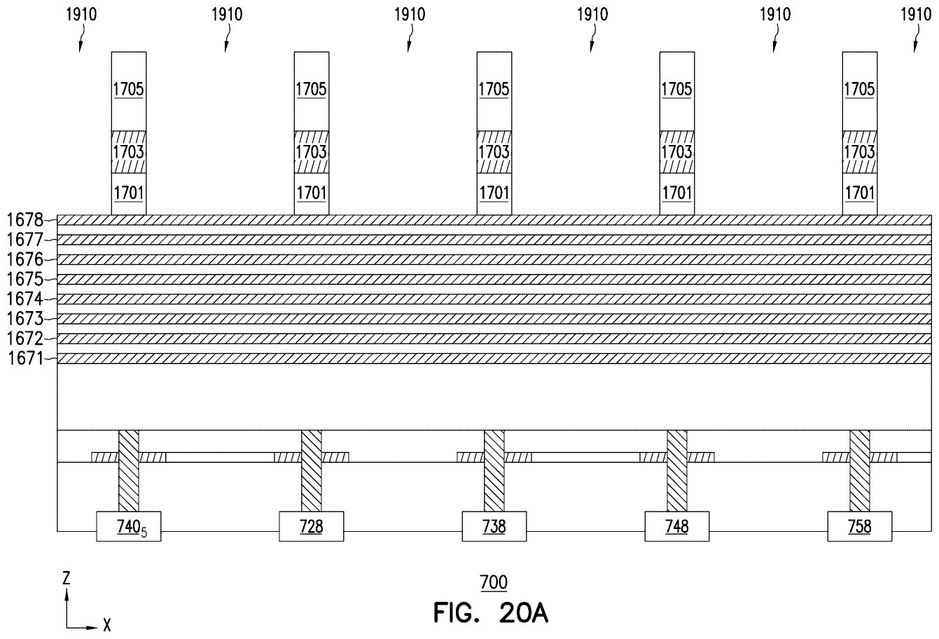

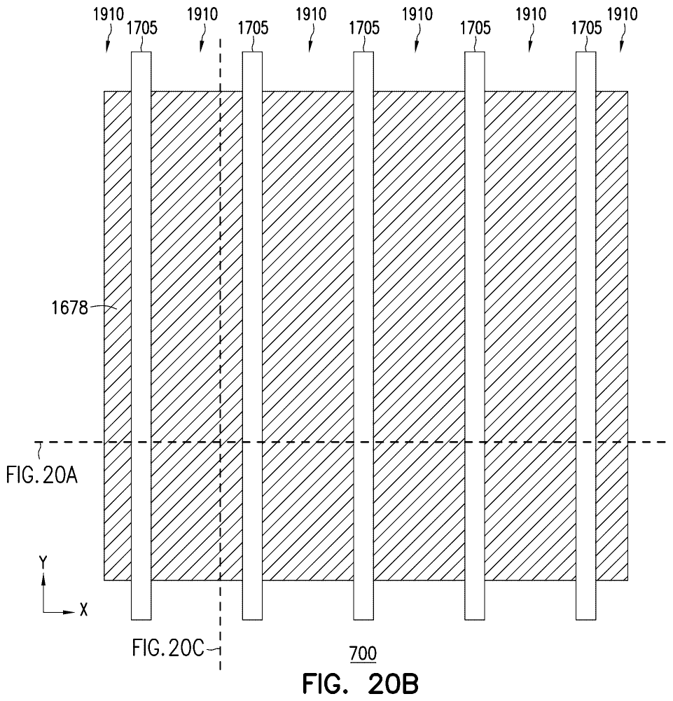

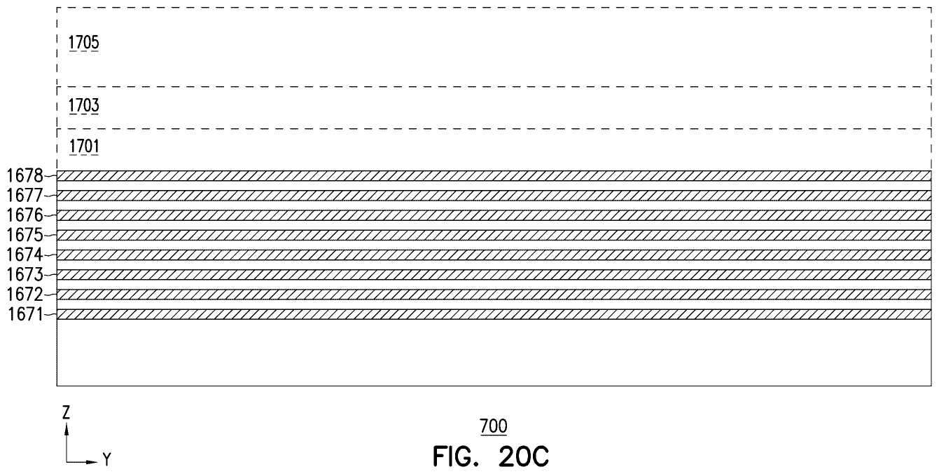

In FIG. 20A, material (e.g., pattern) 1801 is removed. FIG. 20B is a top view of memory device of FIG. 20A. In FIG. 20B, the line labeled FIG. 20A is the location of a cross-section of memory device 700 shown in FIG. 20A. In FIG. 20B, the line labeled FIG. 20C is the location of a cross-section of memory device 700 shown in FIG. 20C.

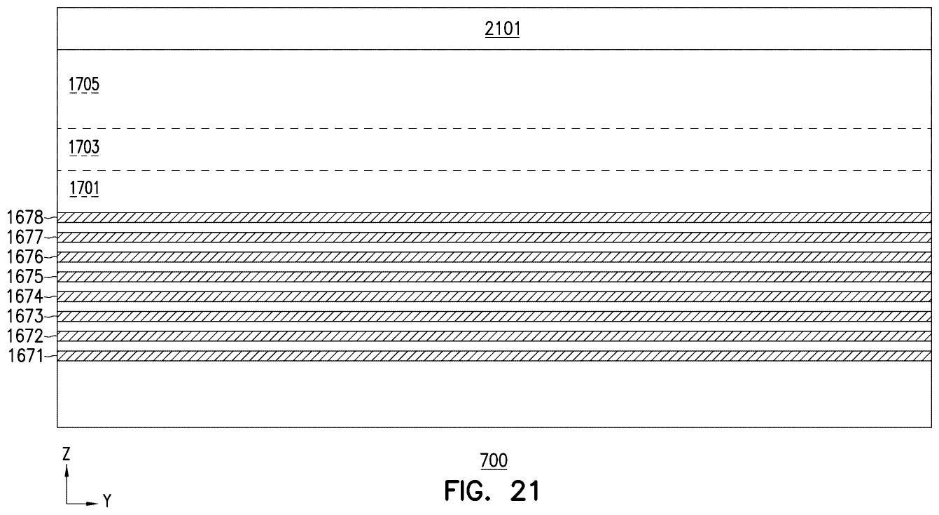

In FIG. 21, a resist structure 2101 is formed. FIG. 21 shows the same view of memory device 700 of FIG. 20C.

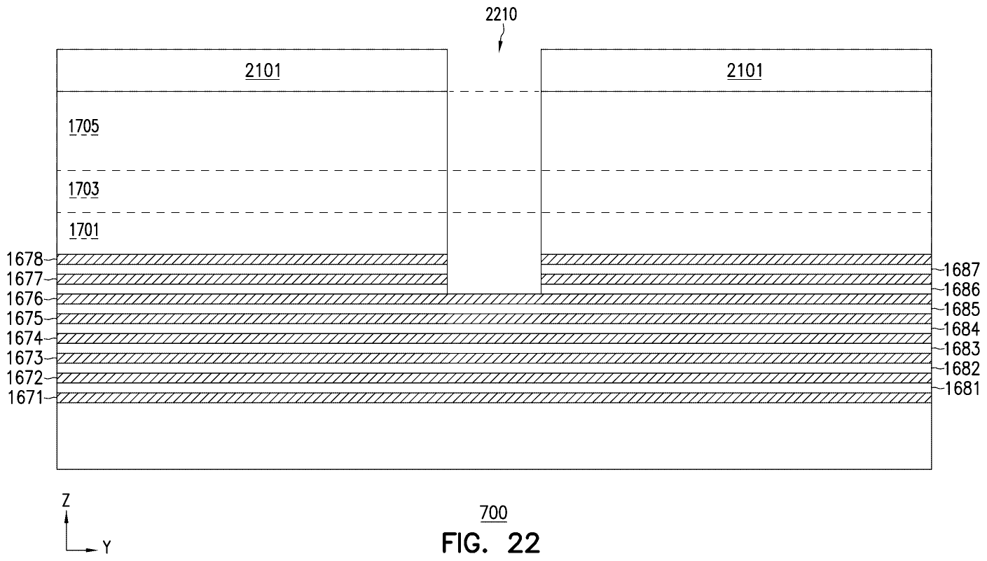

In the following processes associated with FIG. 22 through FIG. 29B, different portions of materials 1671 through 1678 and materials 1681 through 1687 are selectively removed (e.g., removed by using an etch process) in different steps (e.g., different etch process). The materials under material 1705 (FIG. 20B) are not removed (e.g., remain the same) when other portions (e.g., portions not under material 1705) of materials 1671 through 1678 and materials 1681 through 1687 are removed.

In FIG. 22, a portion of resist structure 2101 at a location 2210 is removed. A portion of materials 1671 through 1678 and materials 1681 through 1687 at location 2210 is removed (e.g., removed by using an etch process). FIG. 22 shows a remaining portion (e.g., a first remaining portion) of materials 1671 through 1678 and materials 1681 through 1687.

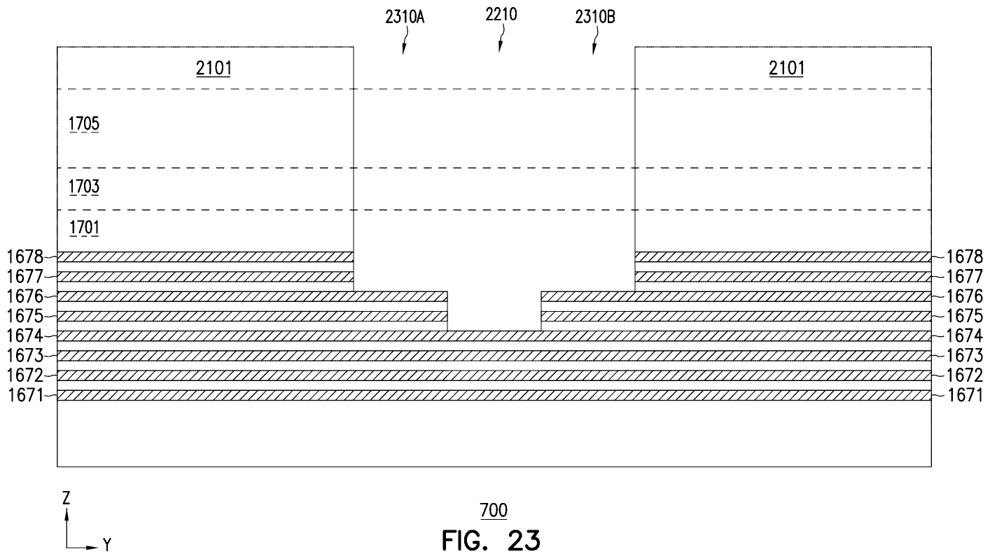

In FIG. 23, a portion of resist structure 2201 at locations 2310A and 2310B is removed (e.g., trimmed). A portion of materials 1671 through 1678 and materials 1681 through 1687 at locations 2210, 2310A, and 2310B is removed (e.g., removed by using an etch process). FIG. 23 shows a remaining portion (e.g., a second remaining portion) of materials 1671 through 1678 and materials 1681 through 1687.

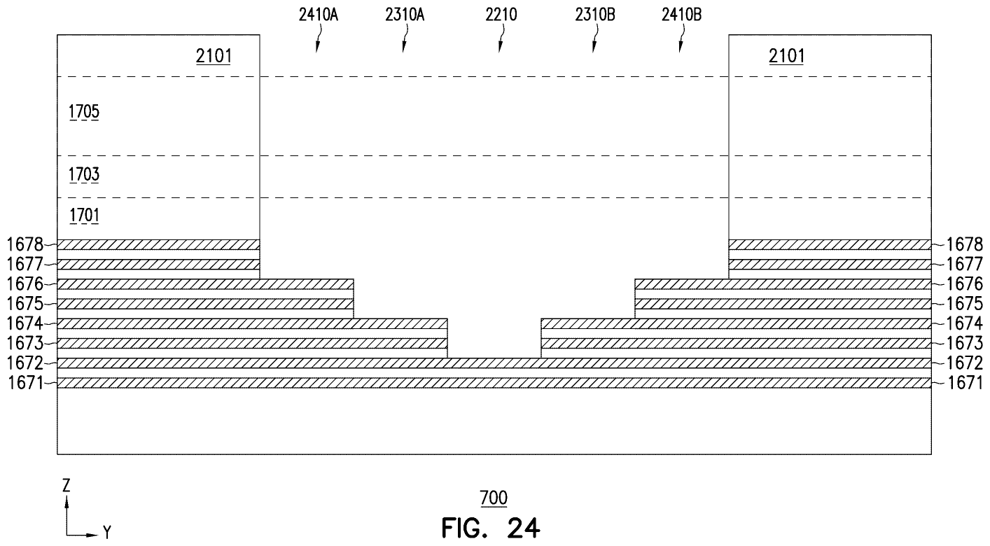

In FIG. 24, a portion of resist structure 2201 at locations 2410A and 2410B is removed (e.g., trimmed). A portion of materials 1671 through 1678 and materials 1681 through 1687 at locations 2210, 2310A, 2310B, 2410A, and 2410B is removed (e.g., removed by using an etch process). FIG. 24 shows a remaining portion (e.g., a third remaining portion) of materials 1671 through 1678 and materials 1681 through 1687.

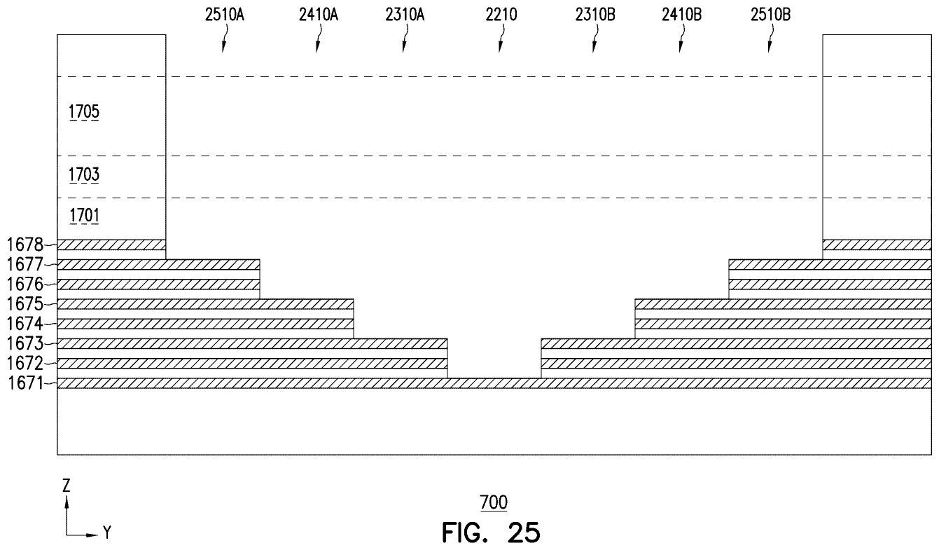

In FIG. 25, a portion of resist structure 2201 at locations 2510A and 2510B is removed (e.g., trimmed). A portion of materials 1671 through 1678 and materials 1681 through 1687 at locations 2210, 2310A, 2310B, 2410A, 2410B, 2510A, and 2510B is removed (e.g., removed by using an etch process). FIG. 25 shows a remaining portion (e.g., a fourth remaining portion) of materials 1671 through 1678 and materials 1681 through 1687.

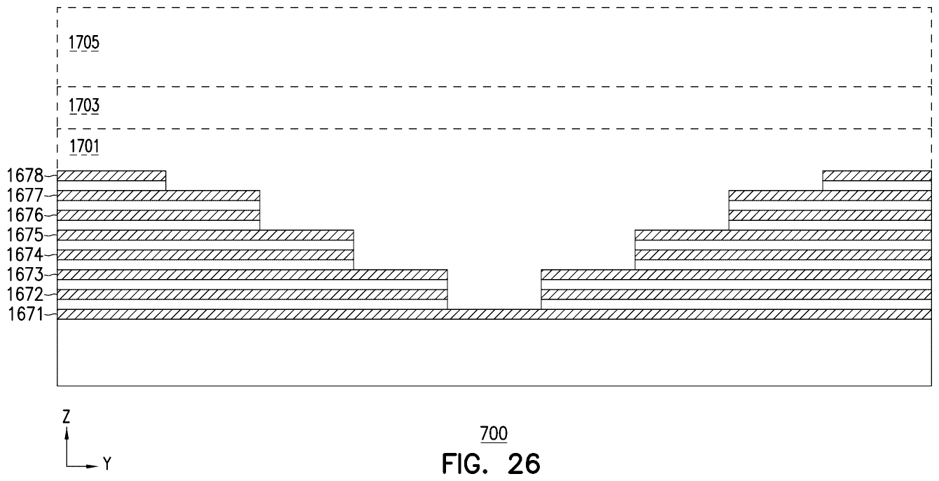

In FIG. 26, resist structure 2101 (FIG. 25) is removed.

FIG. 27 shows memory device 700 after a resist structure 2701 is formed. As shown in FIG. 27, resist structure 2701 can be formed over a portion (e.g., right portion) of remaining portion (e.g., a fourth remaining portion) of materials 1671 through 1678 and materials 1681 through 1687. In FIG. 27, the portion of memory device 700 under resist structure 2701 is part of the portion of memory device 700 at location 717 in FIG. 7. In FIG. 27, portions 2711, 2712, and 2713 (which are not covered by resist structure 2701) will be removed in the process associated with FIG. 28. As shown in FIG. 27, each of portions 2711, 2712, and 2713 can include one of materials 1671 through 1678 and one of materials 1681 through 1687.

In FIG. 28 portions 2711, 2712, and 2713 in FIG. 27 are removed (e.g., removed by using an etch process). FIG. 28 shows the portion of memory device 700 of FIG. 27 including a remaining portion (e.g., a fifth remaining portion) of materials 1671 through 1678 and materials 1681 through 1687 after portions 2711, 2712, and 2713 (FIG. 27) are removed.

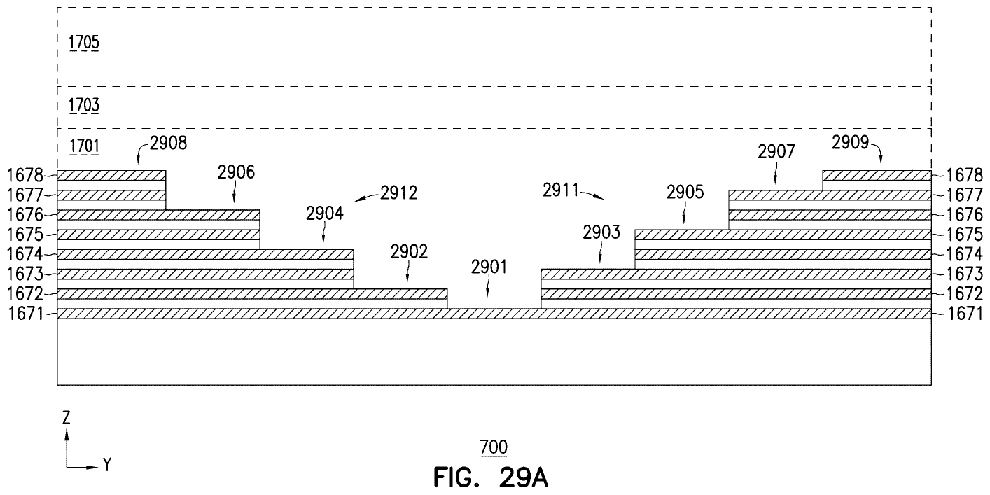

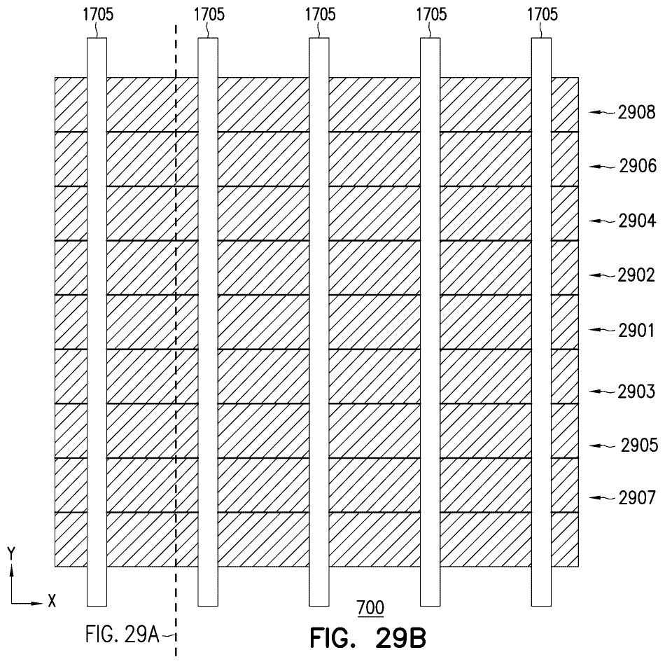

In FIG. 29A, resist structure 2701 (FIG. 28) is removed. FIG. 29B is a top view of memory device 700 of FIG. 29A. In FIG. 29B, the line labeled FIG. 29A is the location of a cross-section of memory device 700 shown in FIG. 29A.

As shown in FIG. 29A, the process of forming memory device 700 (FIG. 7 through FIG. 29A) include forming staircase structures 2911 and 2912 that are opposite from each other (e.g., the stairs of staircase structure 2211 are facing the stairs of staircase structure 2912 in the Y-direction). The stairs of staircase structure 2911 are at uneven levels with the stairs of staircase structure 2912, such that the top exposed portions (e.g., top of the stairs) of staircase structure 2911 of the remaining portions of materials 1671 through 1678 at locations 2901, 2903, 2905, 2907, and 2909 are at uneven levels (in the Z-direction) with the top exposed portions (e.g., top of the stairs) of staircase structure 2912 of the remaining portions of materials 1671 through 1678 at locations 2902, 2904, 2906, and 2908.

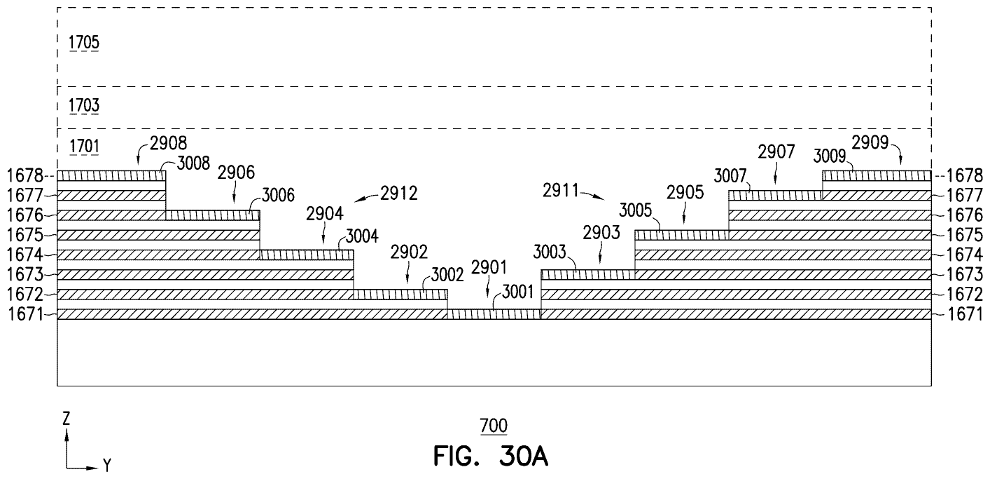

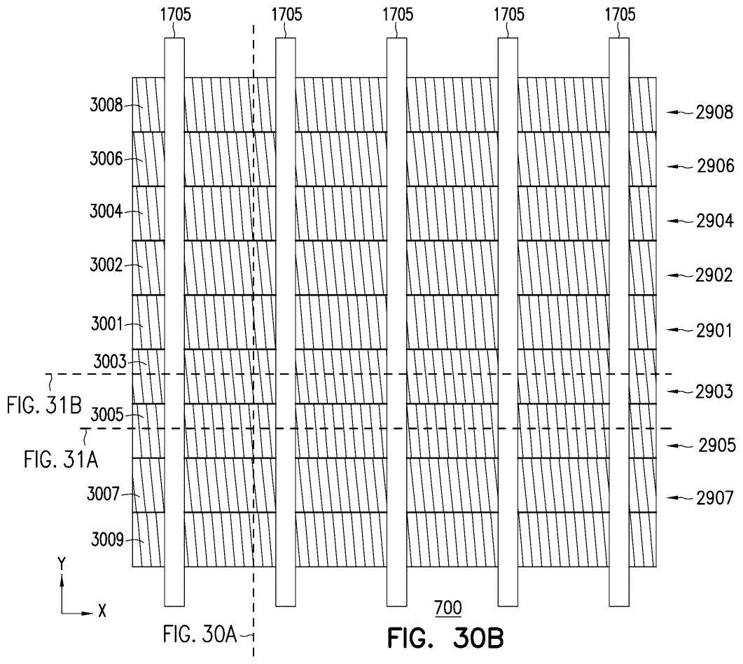

In FIG. 30A, materials 3001, 3003, 3005, 3007, and 3009 are formed at respective locations 2901, 2903, 2905, 2907, and 2909 staircase structure 2911. Materials 3002, 3004, 3006, 3008 are formed at respective locations 2902, 2904, 2906, and 2908 at staircase structure 2912. FIG. 30B is a top view of memory device of FIG. 30A. In FIG. 30B, the line labeled FIG. 30A is the location of a cross-section of memory device 700 shown in FIG. 30A.

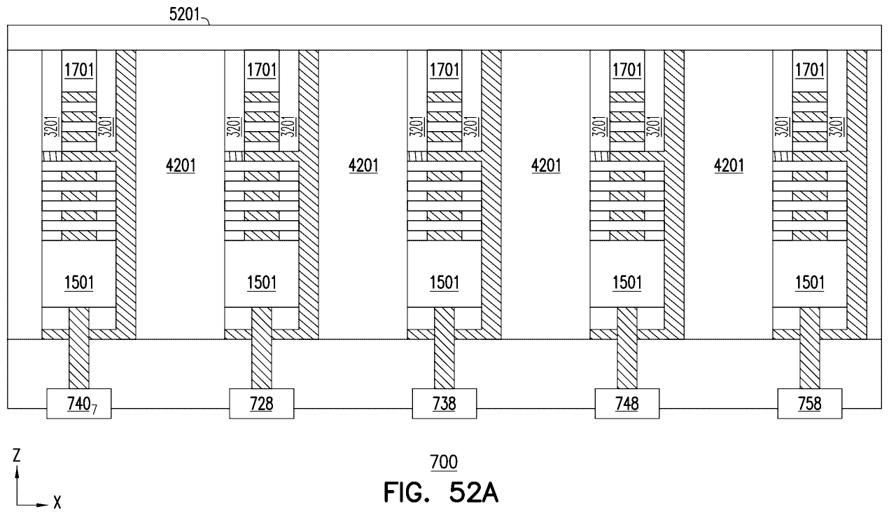

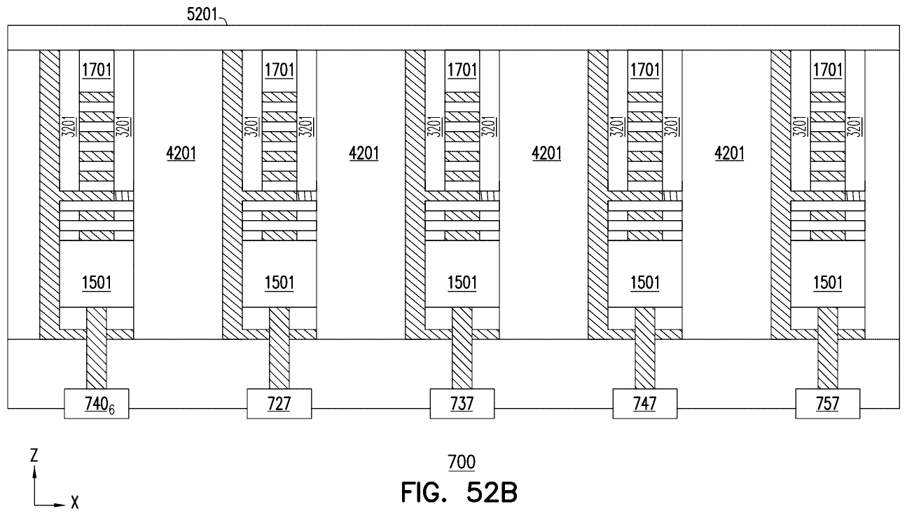

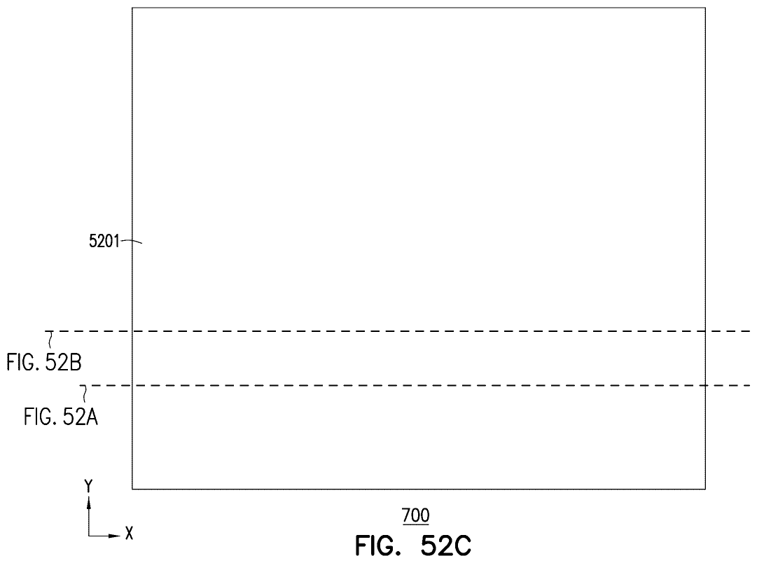

In FIG. 30A, materials 3001 through 3009 can include introducing a material (or materials) into the exposed portions of materials 1671 through 1678 to convert the exposed portions of materials 1671 through 1678 into a different material (e.g., a converted material). For example, carbon can be introduced (e.g., implanted) into the exposed portions of materials 1671 through 1678 to form a material that includes carbon (e.g., silicon carbon nitride). Forming materials 3001 to 3009 can improve processes of forming memory device 700 relative to processes of forming a similar device. For example, forming materials 3001 through 3009 and associated processes allows a lower process step count and largely self-aligned stacked data lines (e.g., data lines 171′₁ through 171′₈, data lines 172′₁ through 172′₈, data lines 173′₁ through 173′₈, and data lines 174′₁ through 174′₈ in FIG. 51C). Forming materials 3001 through 3009 can allow relatively dense interconnect schemes in memory device 700. Forming materials 3001 through 3009 can allow improved connections from the data lines to lower conductive contacts (e.g., conductive contacts 740₇, 728, 738, 748, and 758 in FIG. 52A). Moreover, forming materials 3001 through 3009 allows spacing of dielectric spacers in the stacked data lines to be improved (e.g., optimized), which can lead to reduced capacitance and increased metal thickness, thereby reducing resistance to improve associated RC (resistance-capacitance) conditions in memory device 700. In FIG. 30B, the lines labeled FIG. 31A in FIG. 31B can correspond to lines 792A and 792B, respectively, of FIG. 7.

FIG. 31A and FIG. 31B show different views of memory device 700 of FIG. 30B along the lines labeled FIG. 31A in FIG. 31B, respectively. As shown in FIG. 31A, material 3005 can be seen spanning across respective locations in the X-direction on the same level of memory device 700. As shown in FIG. 31B, material 3003 can be seen spanning across respective locations in the X-direction on the same level of memory device 700.

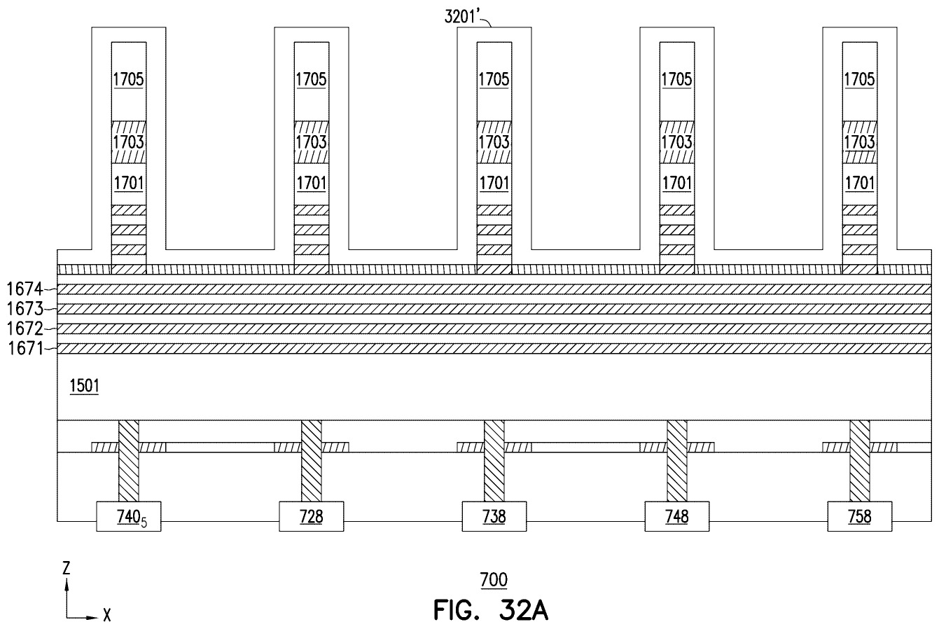

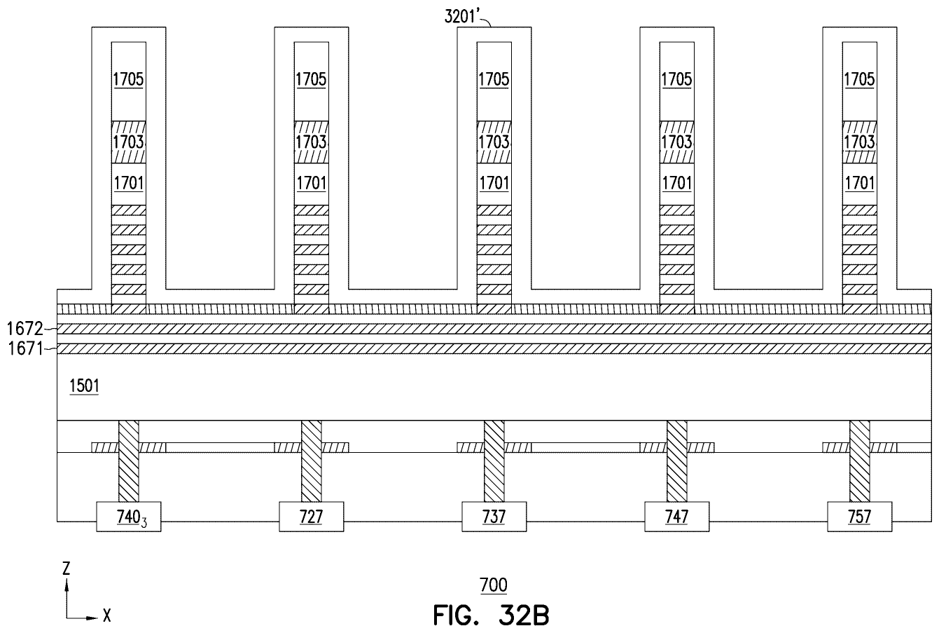

In FIG. 32A and FIG. 32B, a dielectric material (e.g., silicon dioxide) 3201′ is formed over the materials.

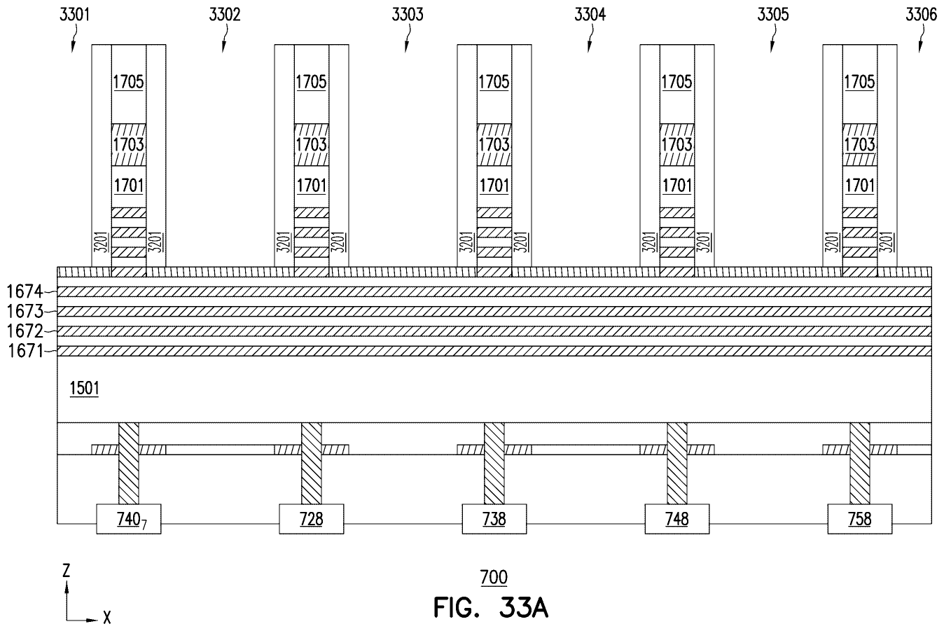

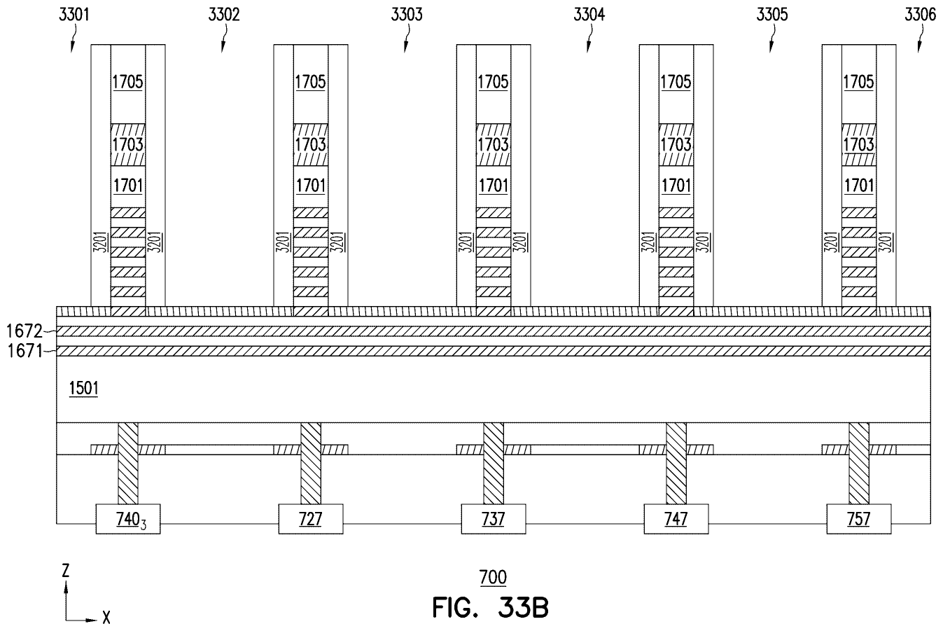

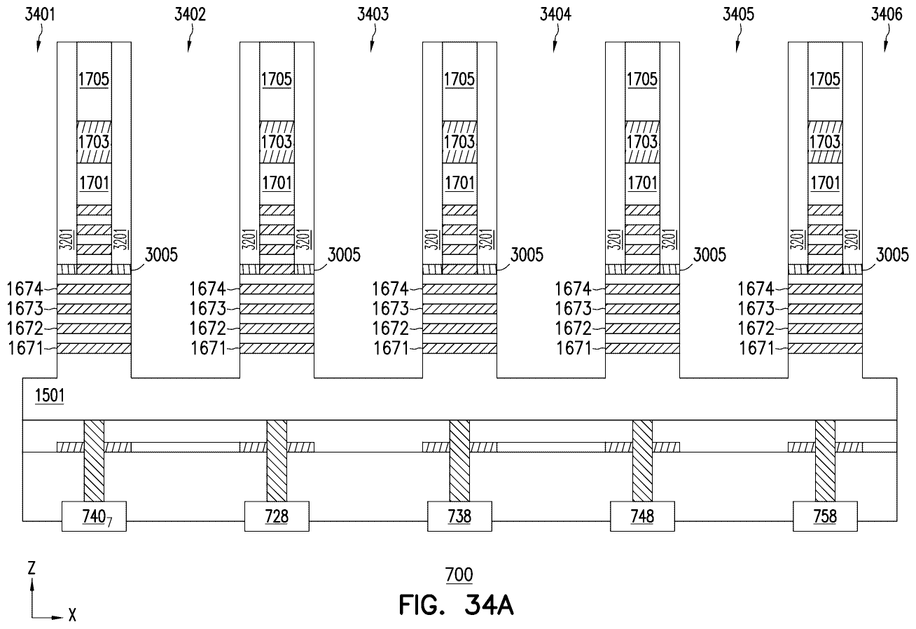

In FIG. 33A and FIG. 33B, spacer (dielectric spacers) 3201 and openings (e.g., trenches) 3301 through 3306 are formed. Forming spacers 3201 and openings 3301 through 3306 can include removing (e.g., etching) a portion (e.g., top portion) of dielectric material 3201′ (labeled in FIG. 32A and FIG. 32B) and respective portions (e.g., horizontal portions) at the locations of openings 3301 through 3306 (FIG. 33A and FIG. 33B). The remaining portion of dielectric material (e.g., silicon dioxide) 3201′ (formed in FIG. 32A and FIG. 32B are further processed in FIG. 33A and FIG. 33B) form spacers 3201. Spacers 3201 can correspond to spacers 345 of memory device 100 of FIG. 5.

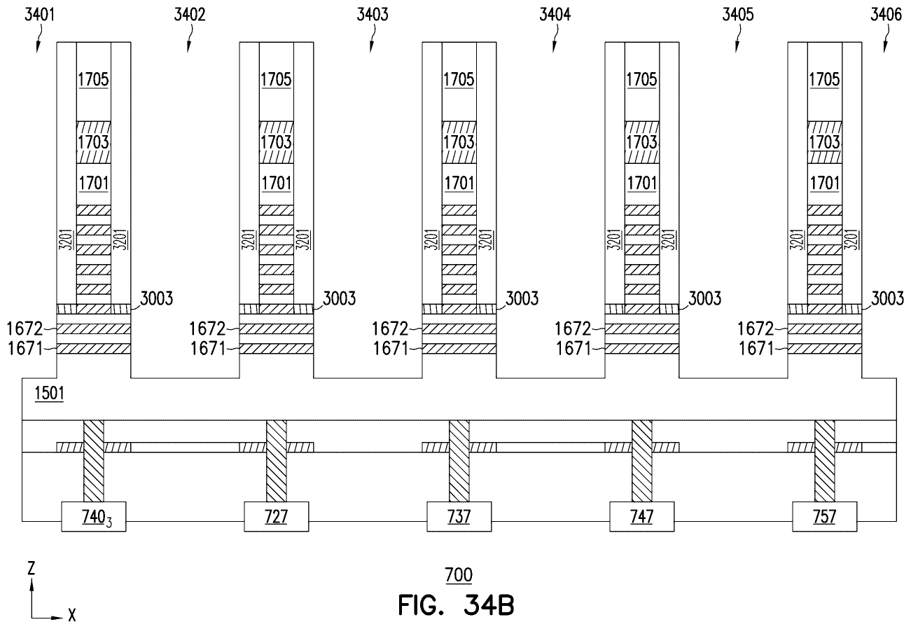

In FIG. 34A and FIG. 34B, openings (e.g., trenches) 3401 through 3406 are formed. Forming openings 3401 through 3406 can include removing (e.g., etching) respective portions of materials 3001 through 3009 and materials 1671 through 1678 and materials 1681 through 1687 at the locations of openings 3301 through 3306 (FIG. 33A and FIG. 33B). As shown in FIG. 34A and FIG. 34B, openings 3401 through 3406 can include trenches that have bottoms at (e.g., formed by) dielectric material 1501.

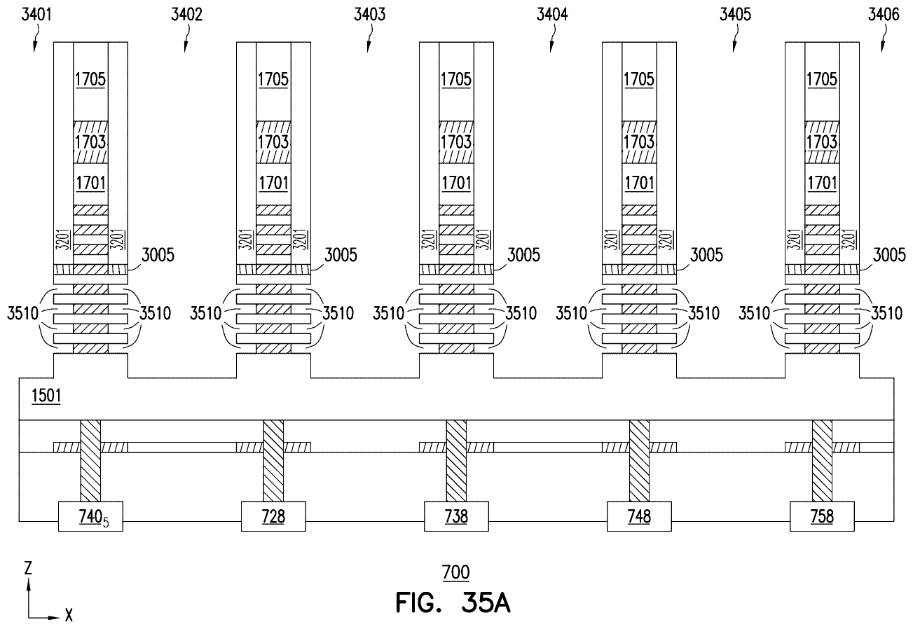

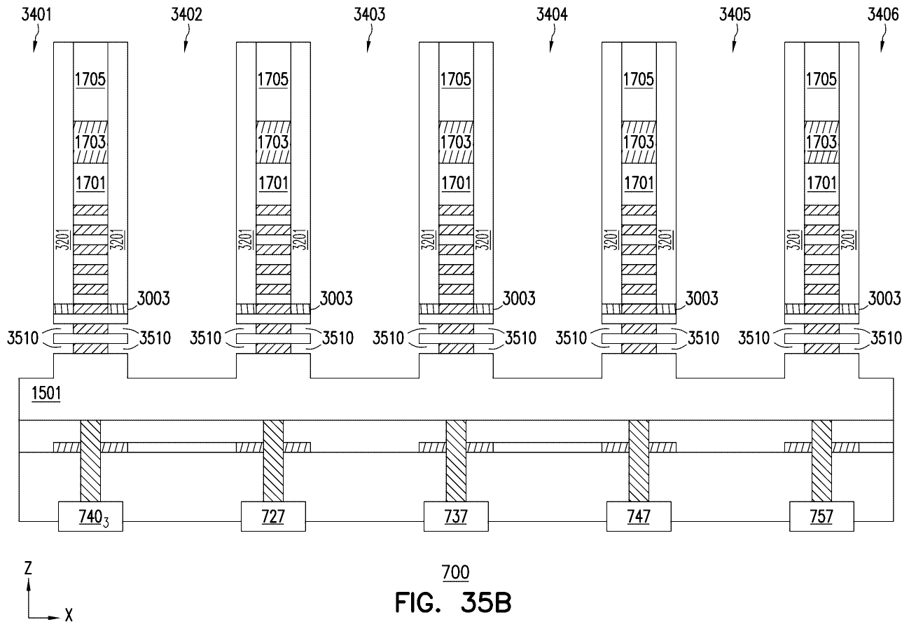

In FIG. 35A and FIG. 35B, a portion of exposed dielectric materials 1671 through 1678 at locations 3510 at openings 3401 are removed (e.g., etched). As shown in FIG. 35A and FIG. 35B, materials 3005 and 3003 are not removed. Similarly, materials 3001, 3002, 3004, and 3006 through 3009 (not shown) are also not removed. As described above, an example for materials 3001 through 3009 includes silicon carbon nitride that is different from dielectric materials (e.g., silicon nitride) 1671 through 1678 to allow materials 3001 through 3009 to remain in memory device 700 during the processes (FIG. 35A and FIG. 35B) of removing exposed dielectric materials 1671 through 1678. However, materials 3001 through 3009 can be materials different from silicon carbon nitride as long as such materials can give etch selectivity and are not removed when dielectric materials (e.g., silicon nitride) 1671 through 1678 are removed in the processes associated with FIG. 35A and FIG. 35B.

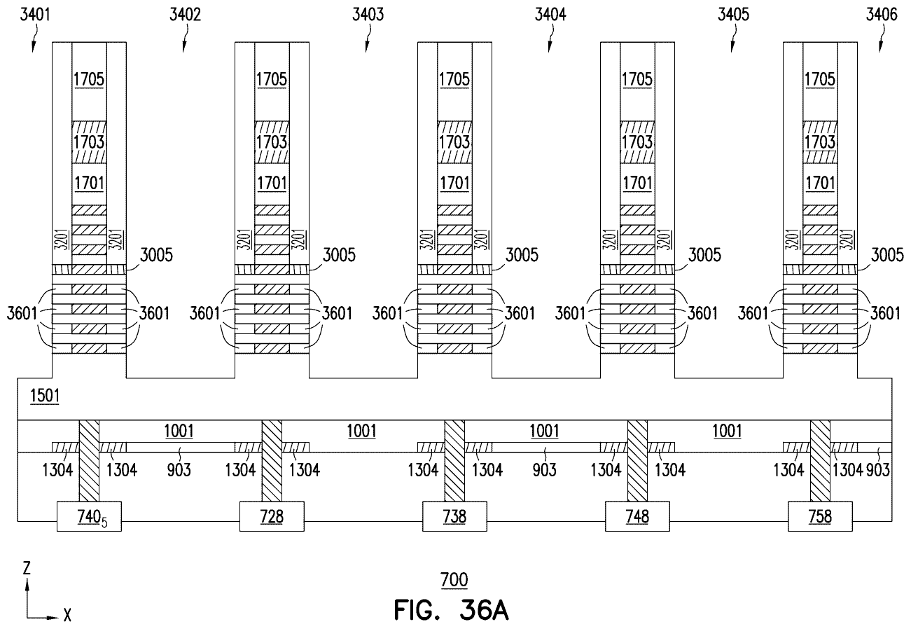

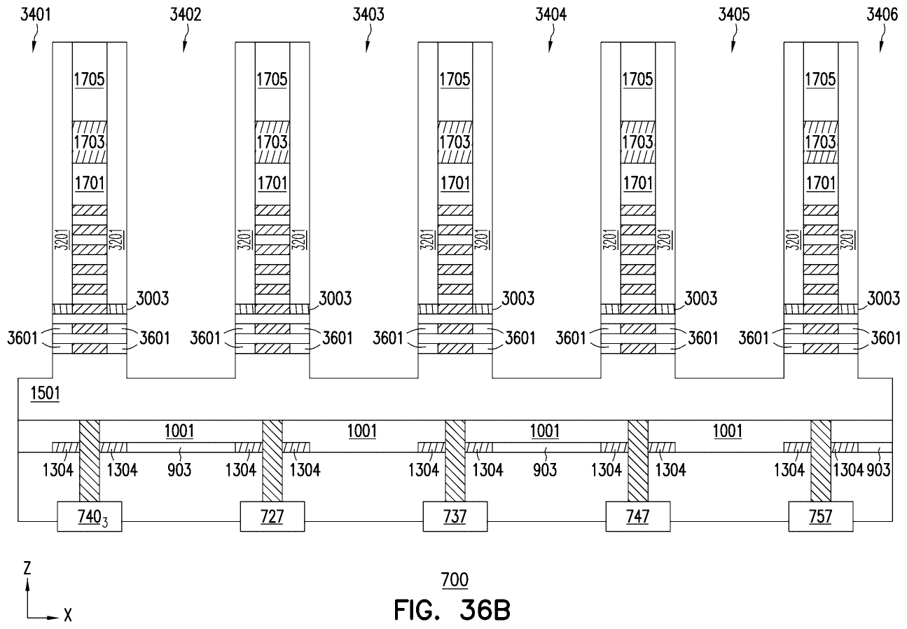

In FIG. 36A and FIG. 36B, dielectric materials (e.g., silicon dioxide) 3601 are formed at respective locations 3510 (FIG. 35A and FIG. 35B).

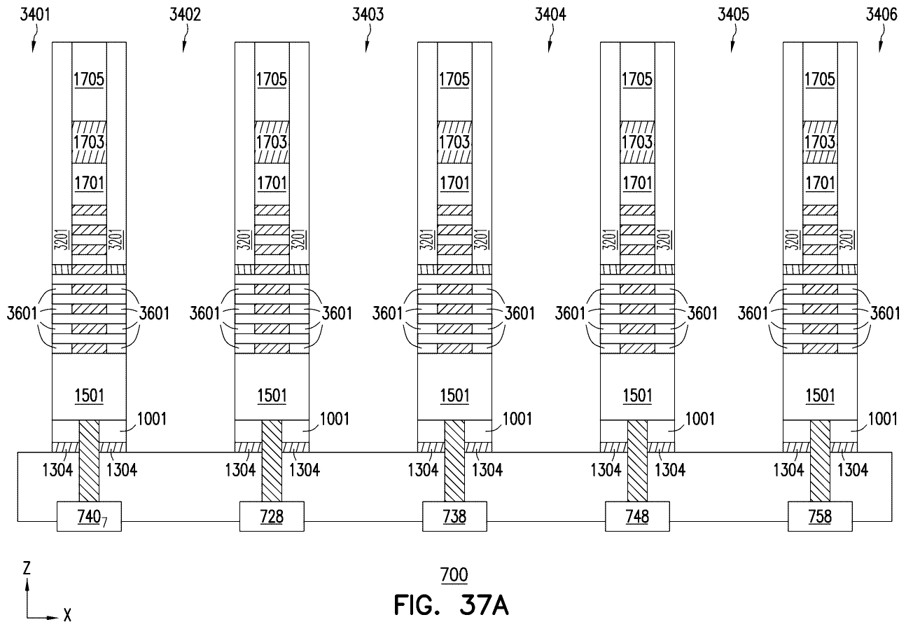

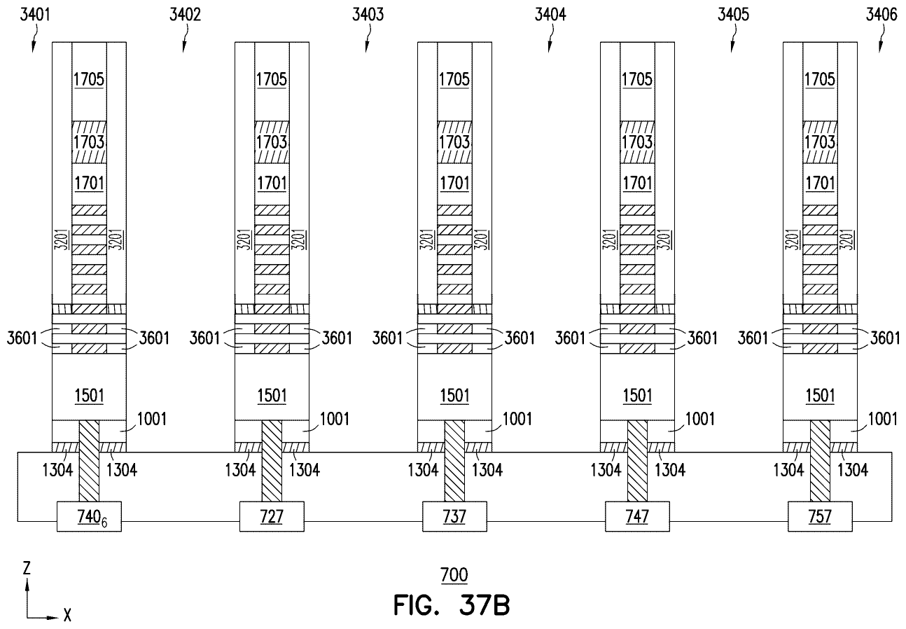

In FIG. 37A and FIG. 37B, a material removal process (e.g., a punch etch process) is performed to remove a portion of each of dielectric materials 1501, 1001, and 903 to expose material (e.g., sacrificial material) 1304 at openings 3401 through 3406.

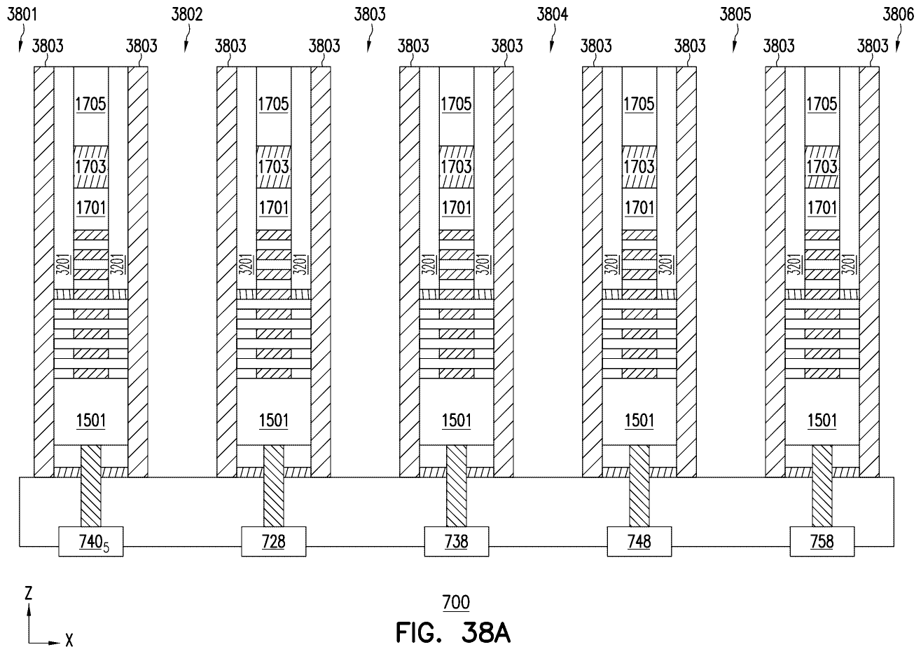

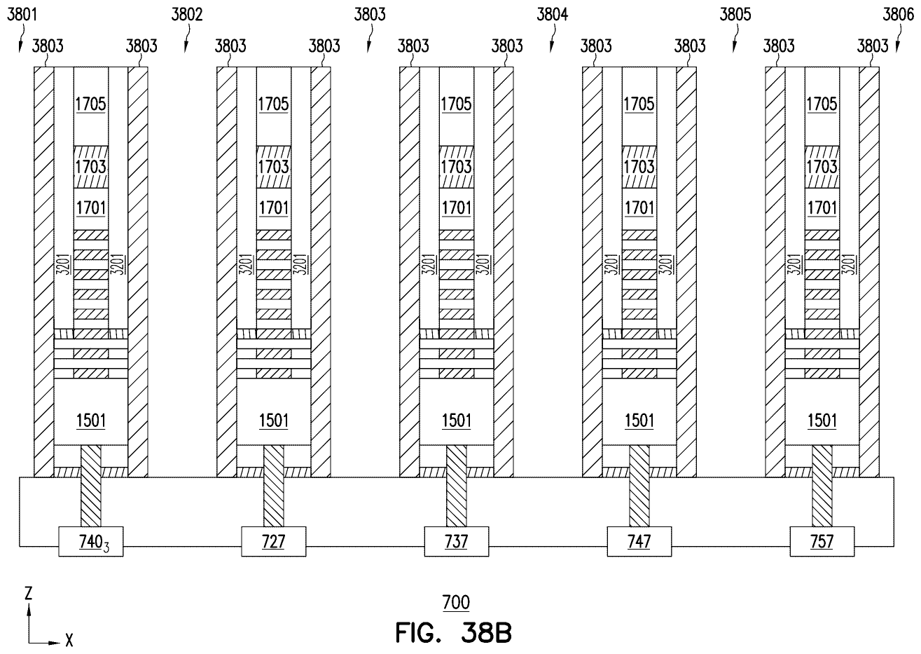

In FIG. 38A and FIG. 38B, spacers (e.g., dielectric spacers) 3803 are formed. Forming spacers 3803 can include forming (e.g., depositing) a dielectric material (e.g., silicon nitride) in openings 3401 through 3406 (FIG. 37A and FIG. 37B) and removing a portion of the dielectric material to form openings 3801 through 3806. The remaining portion of the dielectric material at openings 3601 through 3606 (as shown in FIG. 38A and FIG. 38B) form spacers 3803.

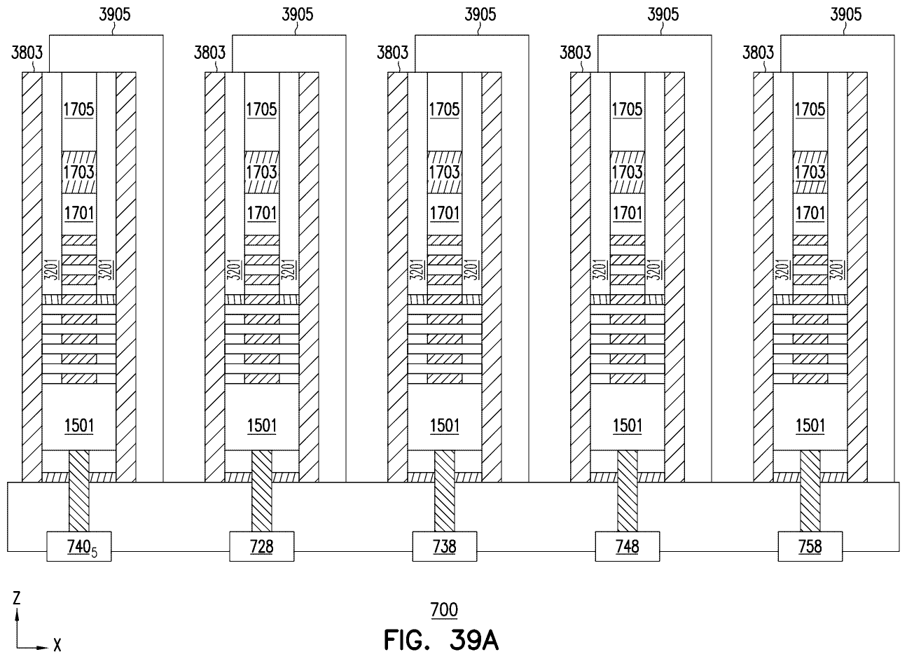

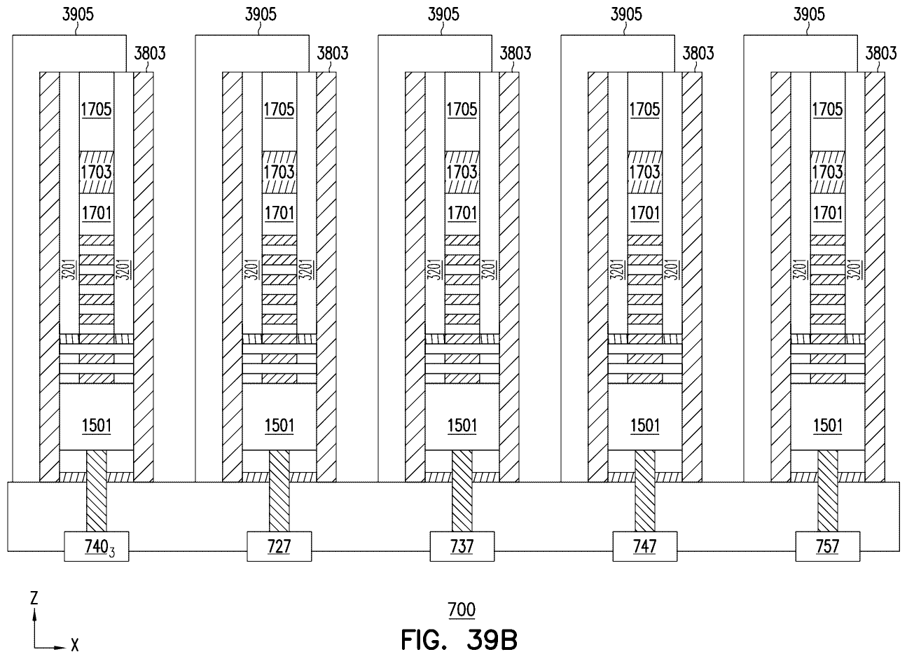

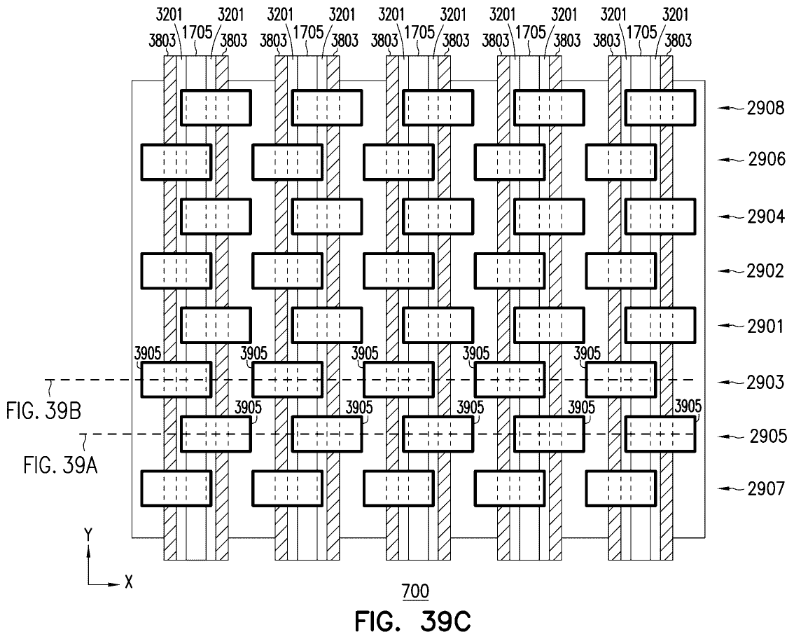

In FIG. 39A and FIG. 39B, resist structures (e.g., resist patterns) 3905 are formed over respective portions of memory device 700. FIG. 39C is a top view of the memory device 700 of FIG. 39A and FIG. 39B. In FIG. 39C, the lines labeled FIG. 39A and FIG. 39B are the locations of cross-sections of memory device 700 shown in FIG. 39A and FIG. 39B, respectively. As shown in FIG. 39A, FIG. 39B, and FIG. 39C, some of spacers (e.g., silicon nitride) 3803 are covered by resist structures 3905. Some other spacers 3803 are exposed (are not covered by resist structures 3905).

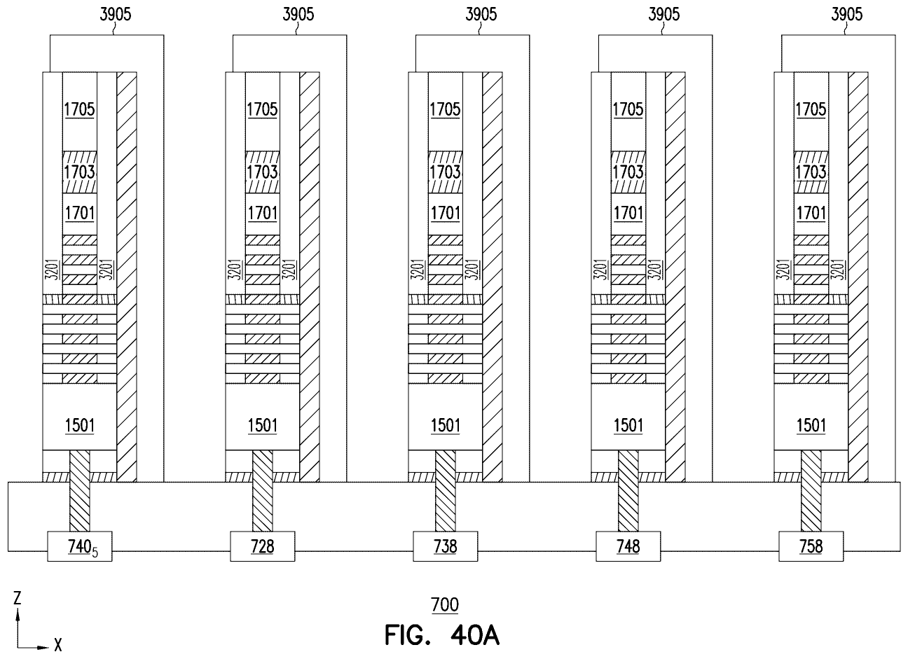

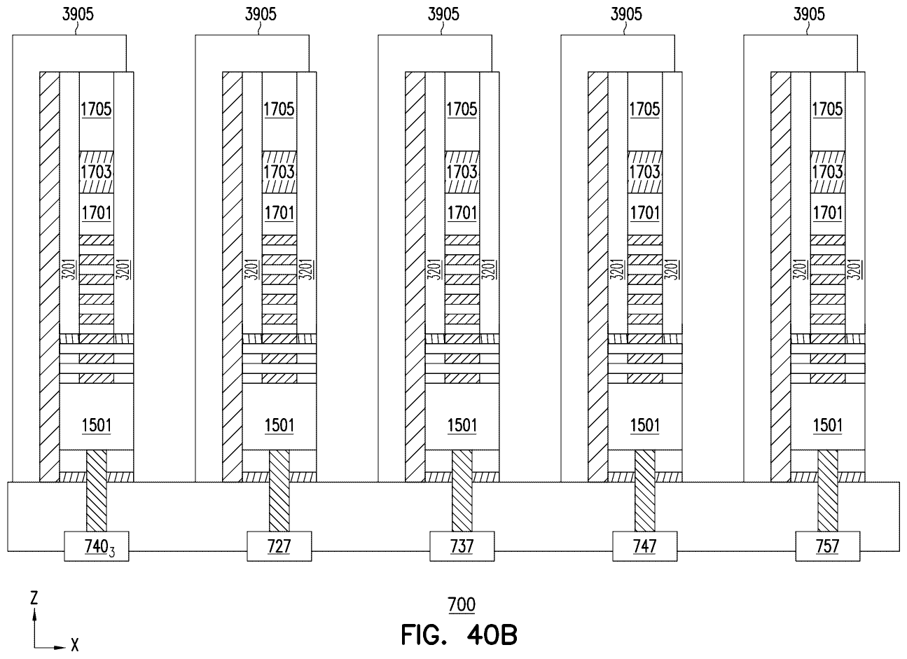

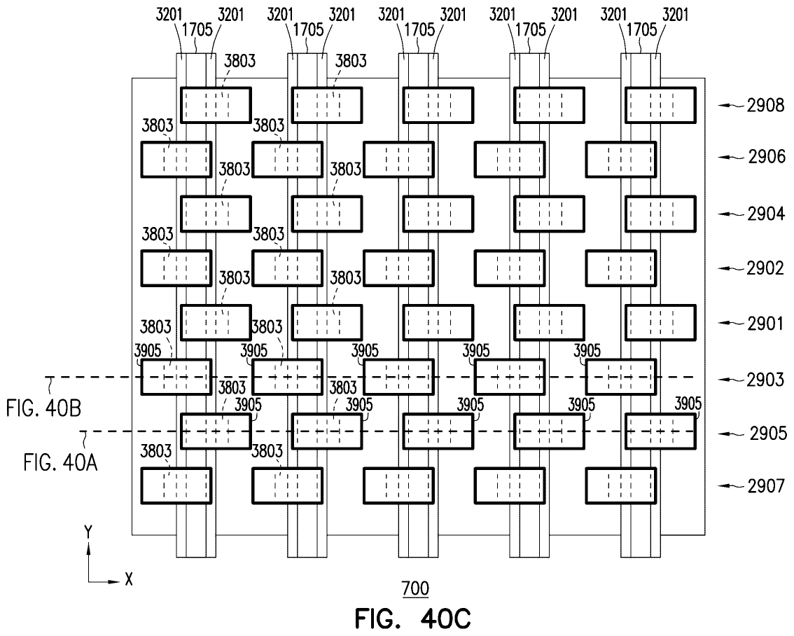

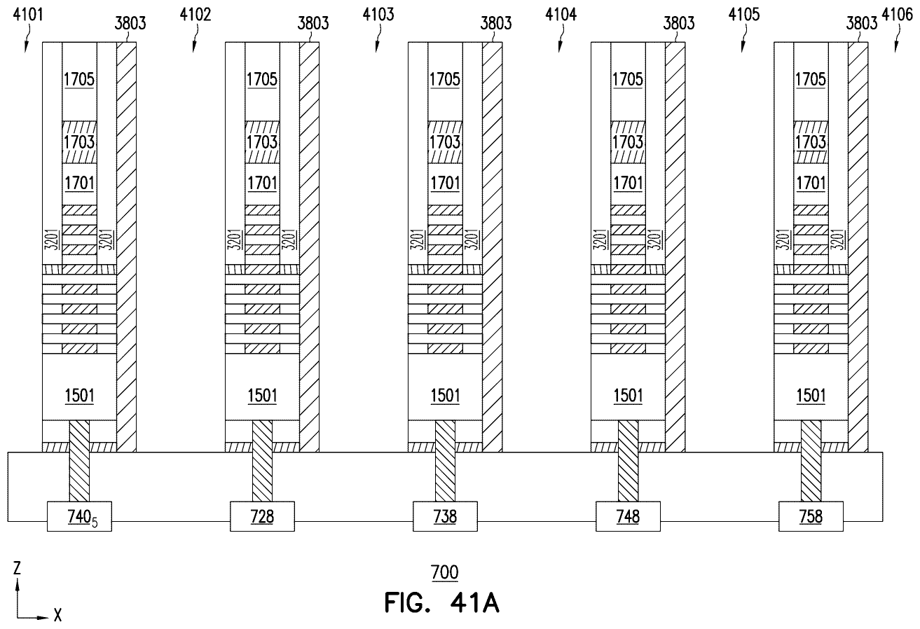

In FIG. 40A and FIG. 40B, some of spacers (e.g., silicon nitride) 3803 (which are exposed in FIG. 39A, FIG. 39B, and FIG. 39C) are removed (e.g., etched). FIG. 40C is a top view of the memory device 700 of FIG. 40A and FIG. 40B. In FIG. 40C, the lines labeled FIG. 40A and FIG. 40B are the locations of cross-sections of memory device 700 shown in FIG. 40A and FIG. 40B, respectively.

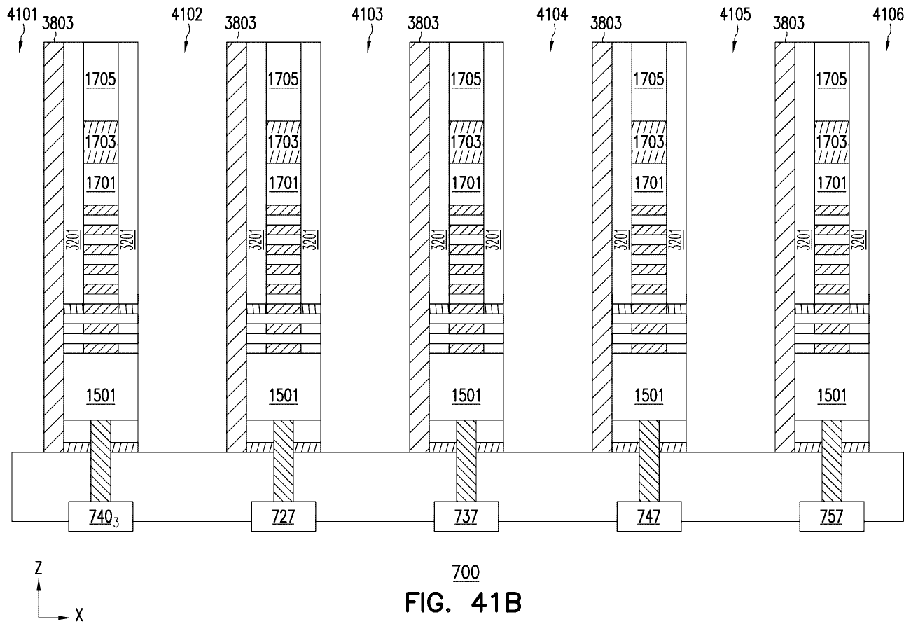

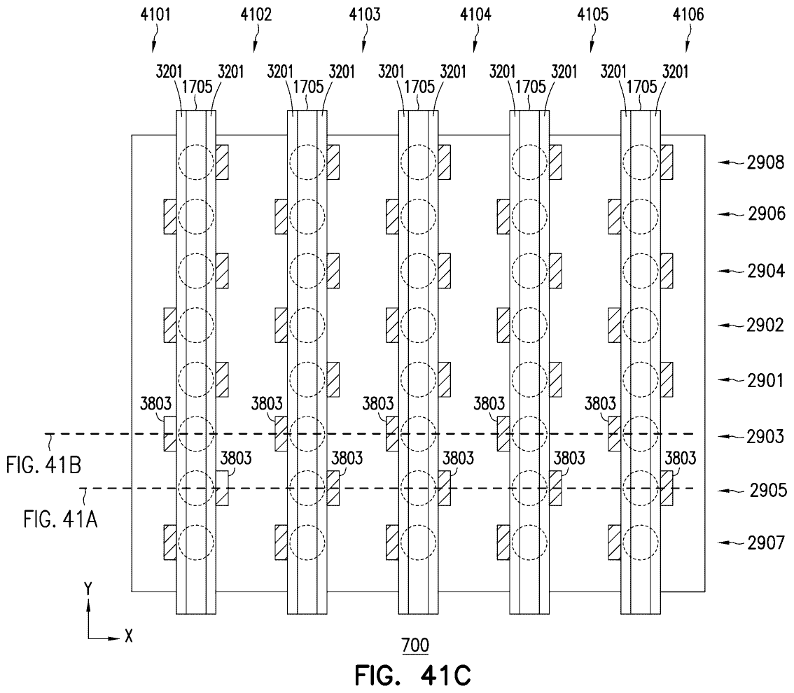

In FIG. 41A and FIG. 41B, resist structures 3905 are removed. FIG. 41C is a top view of the memory device 700 of FIG. 41A and FIG. 41B. In FIG. 41C, the lines labeled FIG. 41A and FIG. 41B are the locations of cross-sections of memory device 700 shown in FIG. 41A and FIG. 41B, respectively. As shown in FIG. 41A, 41B, and FIG. 41C, openings 4101 through 4106 are also formed.

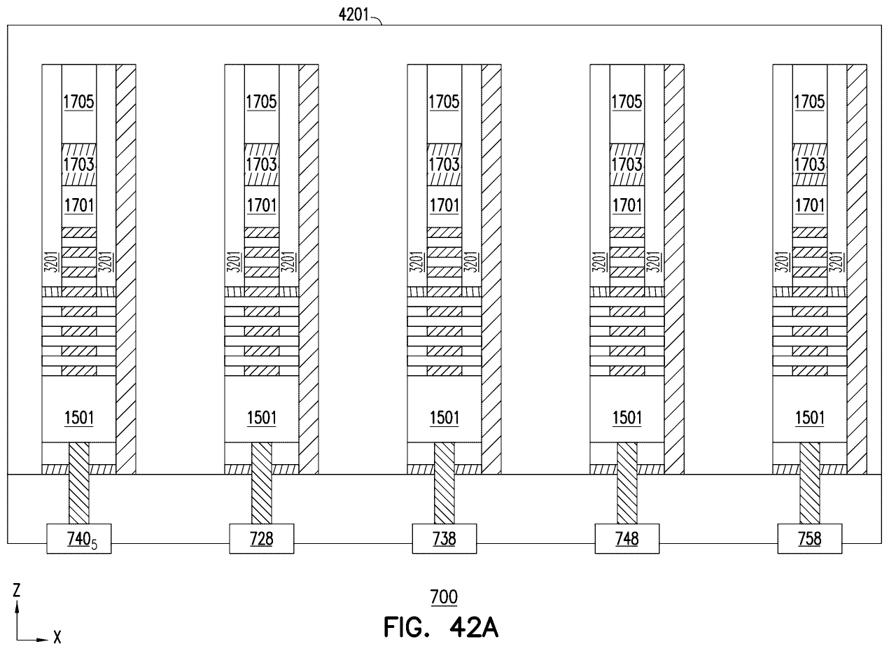

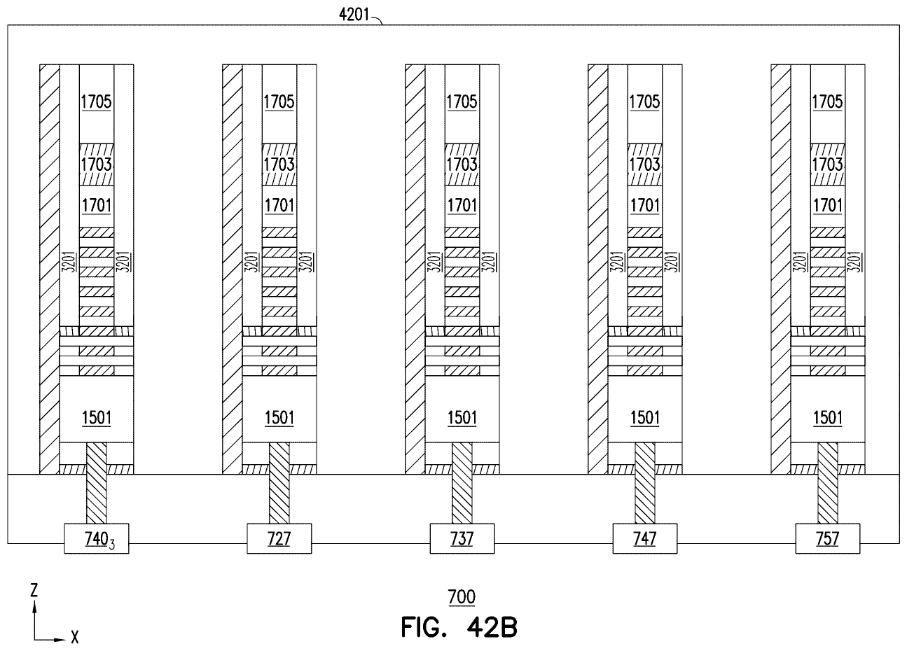

In FIG. 42A and FIG. 42B, a dielectric material (e.g., silicon dioxide) 4201 are formed in openings 4101 through 4106 (labeled in FIG. 41A, 41B, and FIG. 41C) and over other materials of memory device 700 as shown in FIG. 42A and FIG. 42B.

In FIG. 43A and FIG. 43B, a portion (e.g., top portion) of dielectric material 4201 is removed. A process (e.g., CMP process) can also be performed to such that material (e.g., sacrificial material) 1703 is exposed as shown in FIG. 43A and FIG. 43B.

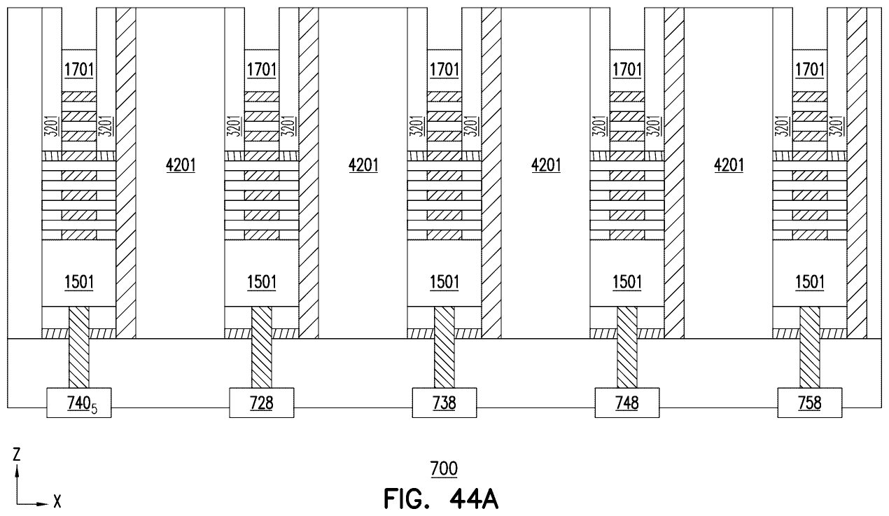

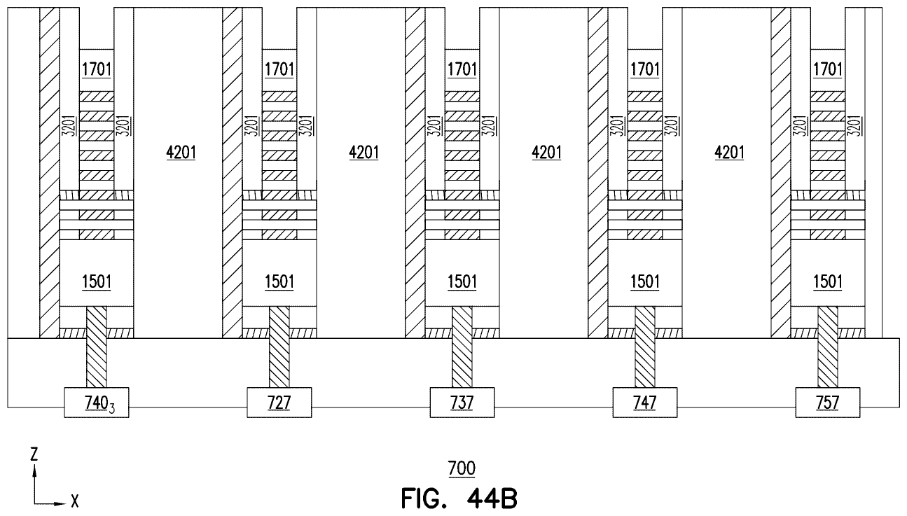

In FIG. 44A and FIG. 44B, material 1703 is removed (e.g., etched).

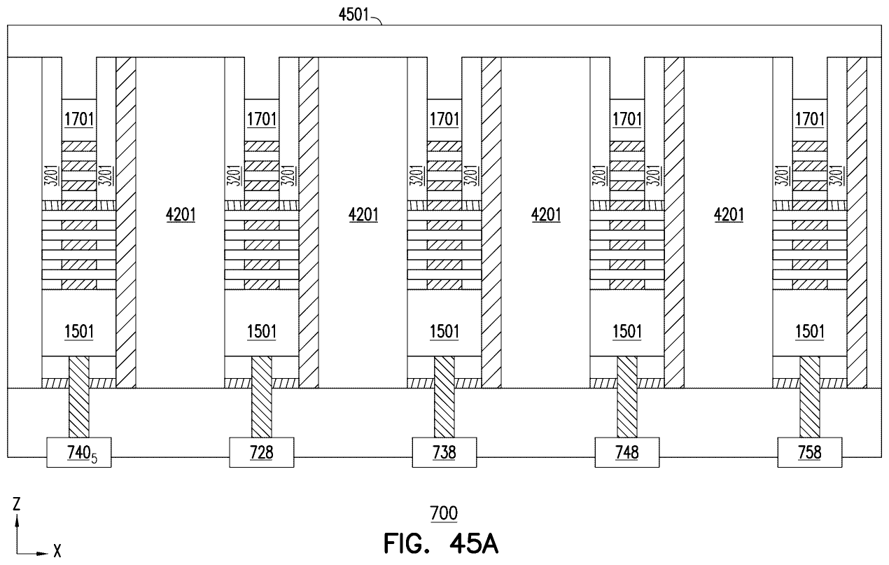

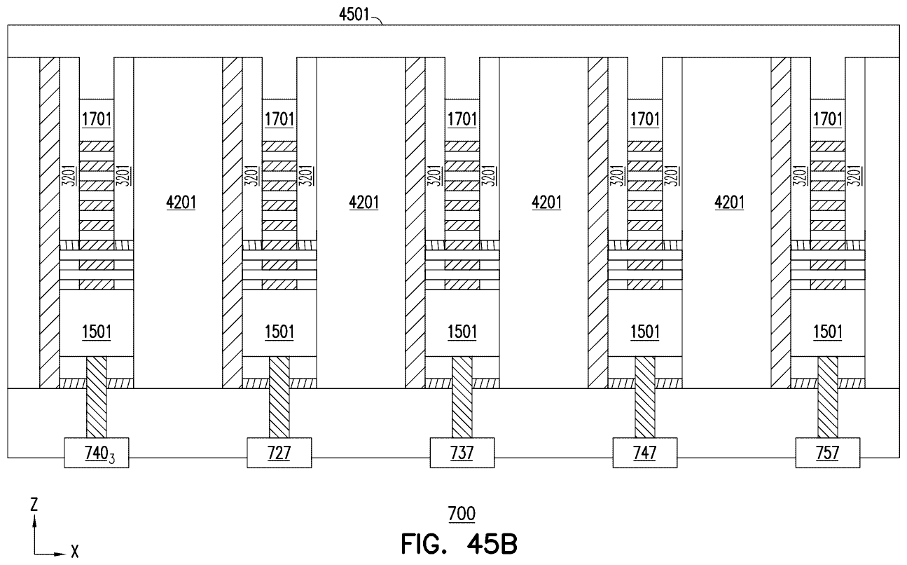

In FIG. 45A and FIG. 45B, a dielectric material (e.g., silicon dioxide) 4501 is formed in the locations of material 1703 (FIG. 44A and FIG. 44B) that was removed. As shown in FIG. 45A and FIG. 45B, dielectric material 4501 is also formed over other materials of memory device 700.

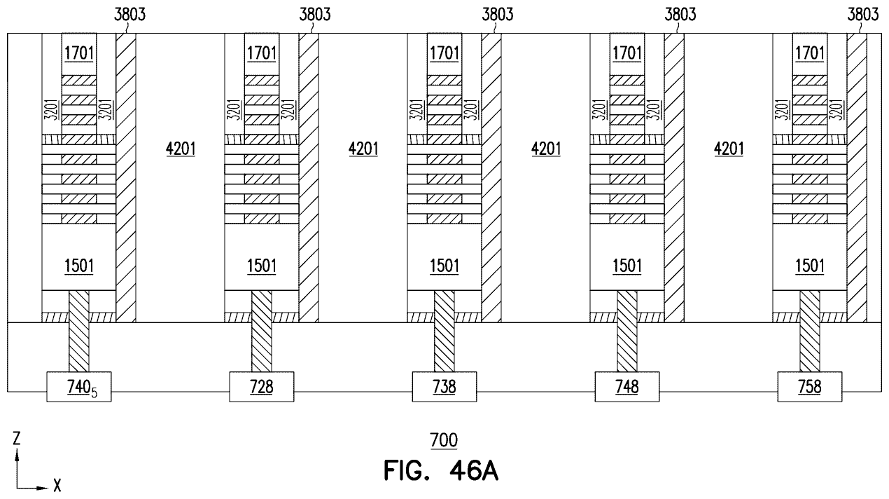

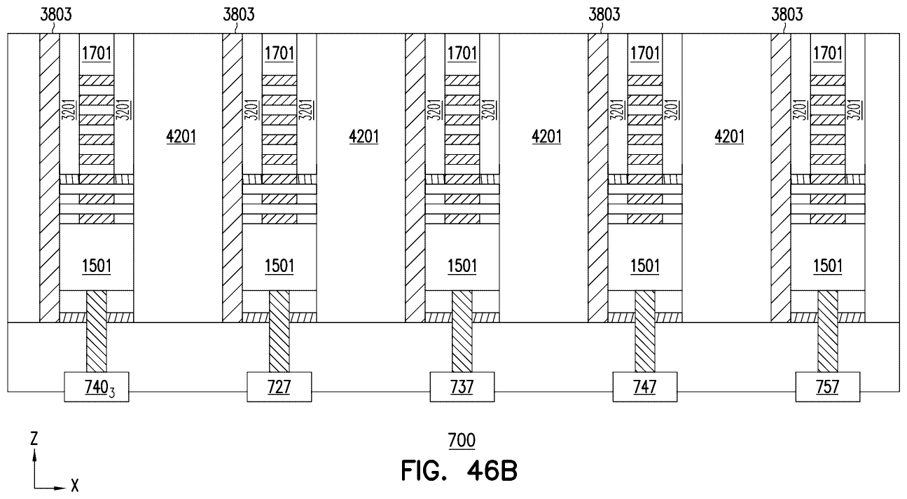

In FIG. 46A and FIG. 46B, a portion (e.g., top portion) of dielectric material 4501 is removed (e.g., using a CMP process). The processes associated with FIG. 46A and FIG. 46B can be performed to expose spacers (e.g., silicon nitride) 3808.

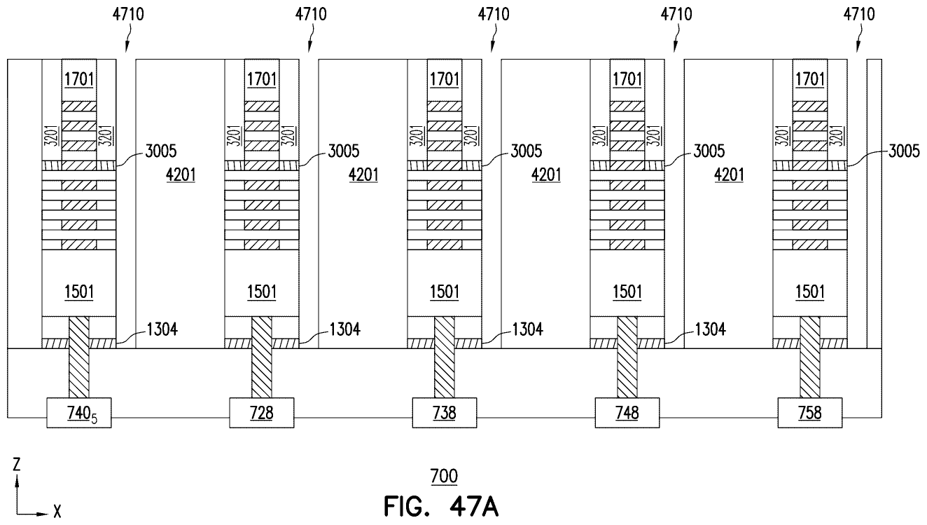

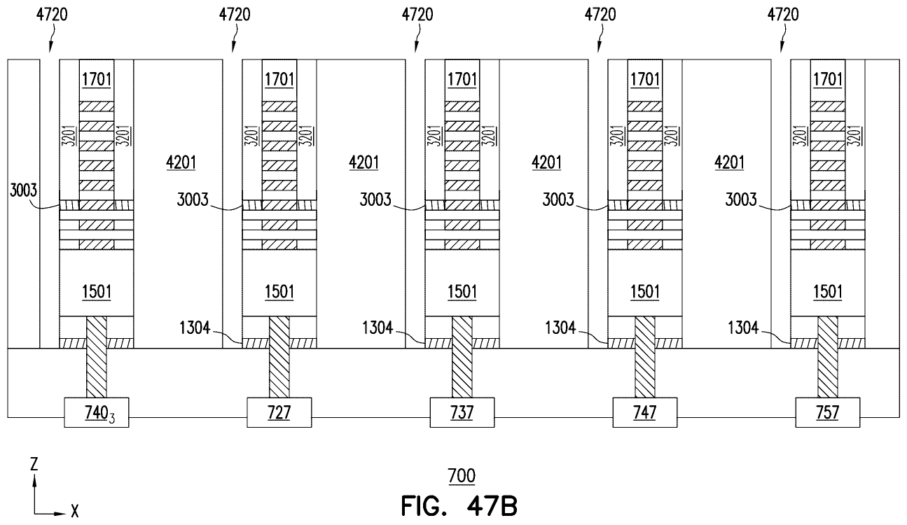

In FIG. 47A and FIG. 47B, spacers (e.g., silicon nitride) 3808 are removed (e.g., exhumed) leaving openings (e.g., voids) 4710 (FIG. 47A) and 4720 (FIG. 47B). As shown in FIG. 47A and FIG. 47B, respective portions of materials 3005 and 3003 are exposed at openings 4710 and 4720, respectively. Respective portions of materials 1304 are also exposed at openings 4710 and 4720, respectively.

In FIG. 48A and FIG. 48B, respective portions of materials 3005 and 3003 (which were exposed at openings 4810 and 4820, respectively) are removed (e.g., exhumed).

In FIG. 49A and FIG. 49B, respective portions of materials 1671 through 1678 (formed in FIG. 16) are removed (e.g., exhumed) from structures (e.g., stack structures) 4970. In FIG. 49A and FIG. 49B, materials 3003 and 3005 (and other portions of materials 3001, 3002, 3004, and 3306 through 3009 (formed in FIG. 30A, not shown in FIG. 49A and FIG. 49B), can remain in memory device 700 (e.g., remain in the final structure of memory device 700). However, in an alternative process, materials 3001 through 3009 (formed in FIG. 30A) can be formed such that materials 3001 through 3009 can also be removed from the structure of memory device 700. For example, in an alternative process associated with FIG. 49A and FIG. 49B, materials 3001 through 3009 can be removed when respective portions of materials 1671 through 1678 are removed (e.g., exhumed) from structures (e.g., stack structures) 4970.

In FIG. 50A and FIG. 50B, respective portions of materials 130₄ (labeled in FIG. 47A and FIG. 47B) are removed (e.g., exhumed).

In FIG. 51A, FIG. 51B, and FIG. 51C, conductive structures 314′₁ through 314′8 are formed. Conductive structures 314′₁ through 314′₈ are coupled to (e.g., electrically in contact with) respective conductive portions 1405. FIG. 51C is a top view of memory device of FIG. 51A and FIG. 51B. In FIG. 51C, the lines labeled FIG. 51A and FIG. 51B are the locations of cross-sections of memory device 700 shown in FIG. 51A and FIG. 51B, respectively.

Each of conductive structure 314′₁ through conductive structure 314′₈ can include a portion (e.g., vertical portion) 5161 and a portion (e.g., horizontal portion) 5162 that can form an L-shape. For simplicity, only some of portions 5161 and 5162 are labeled. As shown in FIG. 51A and FIG. 51B, conductive structure 314′5 (FIG. 51A) and conductive structure 314′₃ (FIG. 51B) can include portion (e.g., vertical portion) 5161 and portion (e.g., horizontal portion) 5162 that can form an L-shape. Portions 5161 and 5612 can correspond to portions 561 and 562 of a respective conductive structure of FIG. 5.

As shown in FIG. 51A, FIG. 51B, and FIG. 51C, memory device 700 can include stacks 5170 through 5174. As shown in FIG. 51C, each of stacks 5170 through 5174 can include data lines (e.g., eight data lines) stacked over each other (in the Z-direction). For example, stack 5170 can include data lines (e.g., eight data lines) 170′₁ through 170′₈ and associated conductive structures 314′₁ through 314′₈. Other stacks include respective data lines 171′₁ through 171′₈, data lines 172′₁ through 172′₈, data lines 173′₁ through 173′₈, and data lines 174′₁ through 174′₈.

Conductive structure 314′₁ through 314′₈ can contact data lines 170′₁ through 170′₈ at respective conductive portions 5101, 5102, 5103, 5104, 5105, 5106, 5107, and 5108, which can be protrusion portions (e.g., an integral part) of respective data lines of the stack of data lines 170′₁ through 170₈. For simplicity, only some of conductive portions 5101 through 5108 are labeled. Conductive portions 5102, 5103, 5106, and 5107 can correspond to conductive portions 502, 503, 506, and 507, respectively, of FIG. 5.

FIG. 51D shows an exploded view of stack 5170 including data lines (e.g., eight data lines) 170′₁ through 170′₈ and associated conductive structures 314′₁ through 314′₈ and conductive portions 5101 through 5108, and materials 3001 through 3008. As shown in FIG. 51D, each of the conductive structures 314′₁ through 314′₈ can be adjacent a side (in the X-direction) of the level of the conductive material of a respective data line, which has a second side (in the X-direction) adjacent a respective material among materials (e.g., silicon carbon nitride) 3001 through 3008.

In FIG. 52A and FIG. 52B, a dielectric material (e.g., silicon dioxide) 5201 is formed over stacks 5170 through 5174 (labeled in FIG. 51A and FIG. 51B). FIG. 52C is a top view of memory device of FIG. 52A and FIG. 52B. In FIG. 52C, the lines labeled FIG. 52A and FIG. 52B are the locations of cross-sections of memory device 700 shown in FIG. 52A and FIG. 52B, respectively.

The processes of forming memory device 700 can include additional processes that are omitted from the description herein. For example, additional processes can be performed to form interconnections and form conductive paths between data lines and other components of memory device 700.

In the above description, memory device 100 and 700 show examples where the conductive contacts (e.g., conductive contacts 340₁ through 340₈ in FIG. 4 and conductive contacts 740₁ through 740₈ in FIG. 7B) are located directly under (e.g., aligned vertically in the Z-direction with) the materials of the data lines (e.g., data lines 170₁ through 170₈ in FIG. 4 and FIG. 5). However, the conductive contacts (e.g., conductive contacts 340₁ through 340₈ in FIG. 4), the memory cell strings (e.g., memory cell strings 130₁ through 130₈ in FIG. 4), or both the conductive contacts and the memory cell strings of memory device 100 or 700 can be located in a pattern that is not directly under the materials of the data lines. For example, in FIG. 4, conductive contacts 340₂, 340₃, 340₆, and 340₇ can be located at respective locations that are offset from the center of the materials of data lines 170₁ through 170₈ (e.g., located on the left, in the X-direction in FIG. 4, of data lines 170₁ through 170₈). In this example, conductive contacts 340₁, 3404, 3405, and 340₈ can be located at respective locations that are offset from the center of the materials of data lines 170₁ through 170₈ (e.g., located on the right, in the X-direction in FIG. 4, of data lines 170₁ through 170₈).

The illustrations of apparatuses (e.g., memory devices 100 and 700) and methods (e.g., method of forming memory device 700) are intended to provide a general understanding of the structure of various embodiments and are not intended to provide a complete description of all the elements and features of apparatuses that might make use of the structures described herein. An apparatus herein refers to, for example, either a device (e.g., memory devices 100 and 700) or a system that includes the device (e.g., memory devices 100 and 700). Although the stacked structure of data lines described herein can be included in a memory device (e.g., memory devices 100 and 700), the stacked structure of data lines described herein can also be included in other semiconductor devices. Example semiconductor devices include processors (e.g., general-purpose processor), application-specific integrated circuits (ASICs)), memory controllers, and other semiconductor devices.

Any of the components described above with reference to FIG. 1 through FIG. 52C can be implemented in a number of ways, including simulation via software. Thus, apparatuses (e.g., memory devices 100 and 700) or part of each of the memory devices and system described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The memory devices (e.g., memory devices 100 and 700) described herein may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 52C include apparatuses and methods of forming the apparatuses. One of the apparatuses includes a conductive contact, a conductive portion formed over the conductive contact, and data lines located over the first conductive portion and separated from the first conductive portion by a dielectric material, the data lines formed from respective levels of conductive materials, and a conductive structure located on a side of the levels of conductive materials. The levels of conductive materials are stacked one over another in a first direction in different levels of the apparatus. The conductive structure includes a first portion and a second portion. The first portion extends in the first direction and coupled to a level of conductive material among the levels of conductive materials. The second portion extends in a second direction and coupled to the conductive portion. Other embodiments, including additional apparatuses and methods, are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
a conductive contact;
a conductive portion formed over the conductive contact;
data lines located over the conductive portion and separated from the first conductive portion by a dielectric material, the data lines formed from respective levels of conductive materials, the levels of conductive materials stacked one over another in a first direction in different levels of the apparatus; and
a conductive structure located on a side of the levels of conductive materials, the conductive structure including a first portion and a second portion, the first portion extending in the first direction and coupled to a level of conductive material among the levels of conductive materials, and the second portion extending in a second direction and coupled to the conductive portion.

2. The apparatus of claim 1, wherein the first portion and the second portion of the conductive structure form an L-shape.

3. The apparatus of claim 1, wherein the second portion of the conductive structure surrounds at least a portion of the conductive portion.

4. The apparatus of claim 1, wherein the first portion of the conductive structure is adjacent a first side of the level of conductive material, and the level of conductive material includes a second side, and wherein a portion of the second side is adjacent a material that includes carbon.

5. The apparatus of claim 1, wherein the first portion of the conductive structure, the second portion of the conductive structure, and the level of conductive material are formed from a same conductive material.

6. The apparatus of claim 1, wherein the first portion, the second portion, and the conductive contact are in electrical contact with a pillar of a memory cells string.

7. An apparatus comprising:
a first conductive portion;
a second conductive portion;
levels of conductive materials stacked over one another and located over the first and second conductive portions;
levels of dielectric materials interleaved with the levels of the conductive materials in a first direction, the levels of conductive materials and the levels of dielectric materials forming a stack of materials;
a first conductive structure located on a first side of the stack of materials and contacting the first conductive portion wherein the first conductive structure contacts a first level of conductive material of the levels of conductive materials, and the first conductive structure includes a portion extending in a second direction and contacting the first conductive portion; and
a second conductive structure located on a second side of the stack of materials and contacting the second conductive portion, wherein the second conductive structure contacts a second level of conductive material of the levels of conductive materials, and the second conductive structure includes a portion extending in the second direction and contacting the second conductive portion.

8. The apparatus of claim 7, further comprising:
a first conductive pillar located under the first conductive portion and contacting the first conductive contact; and
a second conductive pillar located under the second conductive portion and contacting the second conductive contact.

9. The apparatus of claim 7, wherein the levels of conductive materials include a third level of conductive material between the first level of conductive material and the second level of conductive material.

10. The apparatus of claim 7, further comprising a dielectric structure located on the first side of the stack of materials and separating the first conductive structure from the levels of conductive materials except the first level of conductive material.

11. The apparatus of claim 10, further comprising an additional dielectric structure located on the second side of the stack of materials and separating the second conductive structure from the levels of conductive materials except the second level of conductive material.

12. The apparatus of claim 7, further comprising:
a third conductive portion;
a fourth conductive portion, wherein the levels of conductive materials are located over the third and fourth conductive portions;
a third conductive structure located on the first side of the stack of materials and contacting the third conductive portion, wherein the third conductive structure contacts a third level of conductive material of the levels of conductive materials, and the third conductive structure includes a portion extending in the second direction and contacting the third conductive portion; and
a fourth conductive structure located on the second side of the stack of materials and contacting the fourth conductive portion, wherein the fourth conductive structure contacts a fourth level of conductive material of the levels of conductive materials, and the fourth conductive structure includes a portion extending in the second direction and contacting the fourth conductive portion.

13. The apparatus of claim 12, wherein the first level of conductive material, the second level of conductive material, the third level of conductive material, and the fourth level of conductive material are adjacent respective levels of materials silicon carbon nitride.

14. A method comprising:
forming levels of first dielectric materials and levels of second dielectric materials interleaved with the levels of first dielectric materials, the levels of first dielectric materials and the levels of second dielectric materials being formed over conductive contacts of pillars of memory cell strings;
forming a mask structure over the levels of first dielectric materials and the levels of second dielectric materials;
removing first portions of the levels of first dielectric materials and first portions of the levels of second dielectric materials to form a first staircase structure and a second staircase structure in a remaining portion of the levels of first dielectric materials and a remaining portion of the levels of second dielectric materials, wherein the remaining portion of the levels of second dielectric materials includes the levels of first dielectric materials and the levels of second dielectric materials under the mask structure;
converting exposed portions of the levels of second dielectric materials not under the mask structure into a converted material different from the levels of second dielectric materials;
forming stacks of materials, such that each of the stacks of materials includes the levels of first dielectric materials and the levels of second dielectric materials under the mask structure, and portions of the converted material;
removing at least part of the portions of the converted material in the stacks of materials and the levels of second dielectric materials in the stacks of materials; and
forming a conductive material in spaces where at least part of the portions of the converted material in the stacks of materials and the levels of second dielectric materials in the stacks of materials were removed.

15. The method of claim 14, wherein the levels of first dielectric materials includes silicon dioxide and the levels of second dielectric materials comprises silicon nitride.

16. The method of claim 14, converting the exposed portions of the levels of second dielectric materials includes introducing carbon into the exposed portions of the levels of second dielectric materials.

17. The method of claim 14, further comprising:
forming an opening adjacent each of the stacks of materials before forming the conductive material, wherein forming the conductive material includes forming the conductive material in the opening, such that the conductive material in the opening contacts the conductive material in a space where one of the levels of second dielectric materials in the stacks of materials was removed.

18. The method of claim 14, wherein the second staircase structure is opposite from the first staircase structure.

19. The method of claim 14, wherein top exposed portions of the remaining portion of the levels of second dielectric materials of the first staircase structure are at uneven levels with top exposed portions the remaining portion of the levels of second dielectric materials of the second staircase structure.

20. The method of claim 14, wherein the mask structure includes polysilicon.
